(19) United States
(12) Patent Application Publication
(10) Pub. No.: US 2025/0202452 A1
(43) Pub. Date: Jun. 19, 2025

(54) ACOUSTIC WAVE DEVICE

(71) Applicant: Murata Manufacturing Co., Ltd., Nagaokakyo-shi (JP)

(72) Inventors: Yasuhiro SHIMIZU, Nagaokakyo-shi (JP); Daisuke ITO, Nagaokakyo-shi (JP)

(21) Appl. No.: 19/070,672

(22) Filed: Mar. 5, 2025

Related U.S. Application Data
(63) Continuation of application No. PCT/JP2023/034325, filed on Sep. 21, 2023.

(30) Foreign Application Priority Data
Sep. 29, 2022 (JP) 2022-156305

(51) Int. Cl. H03H 9/02; H03H 9/25

(52) U.S. Cl. CPC H03H 9/02889; H03H 9/02559; H03H 9/02574; H03H 9/02866; H03H 9/25

(57) ABSTRACT

An acoustic wave device includes a high acoustic velocity material layer, a piezoelectric layer including lithium tantalate, and an IDT on the piezoelectric layer and including electrode finger portions each including at least one electrode finger portion layer. An acoustic velocity of a bulk wave propagating in the high acoustic velocity material layer is higher than that in the piezoelectric layer. T_{R}=(1/3.15)× (Tₘ/T_{IDT})×100 [%] is satisfied, where T_{R} is a value obtained by dividing a thickness ratio of an Al-equivalent normalized thickness Tₘ of a mass addition film relative to an Al-equivalent normalized thickness T_{IDT} of the electrode finger portion by about 3.15. A wavelength ratio width and a thickness ratio have values within a range on an ellipse and inside of the ellipse on an xy plane expressed by:

x=0.19×cos(−5.5°)×cos θ−

0.021×sin(−5.5°)×sin θ+0.0146×T_{IDT}²−0.229×T_{IDT}+1.5611+0.4×(d−0.55),

and

y=0.19×sin(−5.5°)×cos θ+0.021×cos(−5.5°)×sin θ+10.15.

### CROSS REFERENCE TO RELATED APPLICATIONS

This application claims the benefit of priority to Japanese Patent Application No. 2022-156305 filed on Sep. 29, 2022 and is a Continuation Application of PCT Application No. PCT/JP2023/034325 filed on Sep. 21, 2023. The entire contents of each application are hereby incorporated herein by reference.

### BACKGROUND OF THE INVENTION

### 1. Field of the Invention

The present invention relates to acoustic wave devices.

### 2. Description of the Related Art

Acoustic wave devices have heretofore been widely used in cellular phone filters and the like. Japanese Unexamined Patent Application Publication No. 2019-092095 discloses an example of such an acoustic wave device. In this acoustic wave device, an IDT electrode is provided on a piezoelectric substrate. The IDT (interdigital transducer) electrode includes a central region and a pair of low acoustic velocity regions. The pair of low acoustic velocity regions sandwich the central region in a direction of extension of electrode fingers of the IDT electrode. Each of the low acoustic velocity regions is provided with a mass addition film. A product of a wavelength normalized film thickness of the mass addition film and a density of the mass addition film is set equal to or below 13.4631. Here, the wavelength normalized film thickness is a film thickness that is normalized by a wavelength to be defined by an electrode finger pitch of the IDT electrode. The above-described configuration aims to suppress spurious response due to a transverse mode.

As a result of investigations, the inventors of example embodiments of the present invention have discovered that a degree of an effect to suppress the spurious response due to the transverse mode varies depending on film thicknesses of the electrode fingers of the IDT electrode and on a duty ratio.

### SUMMARY OF THE INVENTION

Example embodiments of the present invention provide acoustic wave devices each able to reduce or prevent a transverse mode more reliably.

An acoustic wave device according to an example embodiment of the present invention includes a high acoustic velocity material layer, a piezoelectric layer on the high acoustic velocity material layer and including lithium tantalate, and an interdigital transducer (IDT) on the piezoelectric layer and including multiple electrode finger portions each including at least one electrode finger portion layer, in which an acoustic velocity of a bulk wave that propagates in the high acoustic velocity material layer is higher than an acoustic velocity of an acoustic wave that propagates in the piezoelectric layer, when a direction of extension of the multiple electrode finger portions is defined as an electrode finger portion extending direction and when the IDT is viewed in a direction orthogonal or substantially orthogonal to the electrode finger portion extending direction, a region where the adjacent electrode finger portions overlap each other is an intersection region, and the intersection region includes a central region and a pair of edge regions sandwiching the central region in the electrode finger portion extending direction, the acoustic wave device further includes a mass addition film at least one of the edge regions and continuously provided so as to overlap the multiple electrode finger portions and regions between the electrode finger portions in plan view, a resonant frequency is higher than about 1 GHz, when a wavelength defined by an electrode finger portion pitch of the IDT is denoted by λ, a value obtained by dividing a product of a density and a thickness of an arbitrary layer by a density of Al and the wavelength λ and expressed in percentage is defined as an Al-equivalent normalized thickness of the layer, a sum of the Al-equivalent normalized thicknesses of the electrode finger portion layers is defined as T_{IDT} [%] representing the Al-equivalent normalized thickness of the plurality of electrode finger portions, the Al-equivalent normalized thickness of the mass addition film is defined as Tₘ[%], and a value obtained by dividing a thickness ratio of the Al-equivalent normalized thickness Tₘ of the mass addition film relative to the Al-equivalent normalized thickness T_{IDT} of the plurality of electrode finger portions by about 3.15 is defined as T_{R} [%], T_{R}=(1/3.15)×(Tₘ/T_{IDT})×100 [%] is satisfied, and when a duty ratio of the IDT is denoted by d, a value obtained by dividing a dimension in the electrode finger portion extending direction of the mass addition film by the wavelength λ is defined as a wavelength ratio width W, a value x corresponds to a value of the wavelength ratio width W, and a value y corresponds to a value of the thickness ratio T_{R}, the wavelength ratio width W and the thickness ratio T_{R} have values within a range on an ellipse and inside of the ellipse on xy plane expressed by a Formula 1 and a Formula 2 while setting a value θ equal to or above 0° and below 360°:

$$x = 0.19 \times cos ( - 5.5 ° ) \times cos θ - 0.021 \times sin ( - 5.5 ° ) \times sin θ + 0.0146 \times {T}_{IDT}^{2} - 0.229 \times {T}_{IDT} + 1.5611 + 0.4 \times ( d - 0.55 ) ; and \qquad ( Formula 1 )$$

$$y = 0.19 \times sin ( - 5.5 ° ) \times cos θ + 0.021 \times cos ( - 5.5 ° ) \times sin θ + 10.15 . \qquad ( Formula 2 )$$

An acoustic wave device according to another example embodiment of the present invention includes a high acoustic velocity material layer, a piezoelectric layer on the high acoustic velocity material layer and including lithium tantalate, and an interdigital transducer (IDT) on the piezoelectric layer and including multiple electrode finger portions each including at least one electrode finger portion layer, in which an acoustic velocity of a bulk wave that propagates in the high acoustic velocity material layer is higher than an acoustic velocity of an acoustic wave that propagates in the piezoelectric layer, when a direction of extension of the multiple electrode finger portions is defined as an electrode finger portion extending direction and when the IDT is viewed in a direction orthogonal or substantially orthogonal to the electrode finger portion extending direction, a region where the adjacent electrode finger portions of the plurality of electrode finger portions overlap each other is an intersection region, and the intersection region includes a central region and a pair of edge regions sandwiching the central region in the electrode finger portion extending direction, the acoustic wave device further includes a mass addition film on at least one of the edge regions and continuously provided so as to overlap the multiple electrode finger portions and regions between the electrode finger portions in plan view, a resonant frequency is higher than about 1 GHz, when a wavelength defined by an electrode finger portion pitch of the IDT is denoted by λ, a value obtained by dividing a product of a density and a thickness of an arbitrary layer by a density of Al and the wavelength λ and expressed in percentage is defined as an Al-equivalent normalized thickness of the layer, a sum of the Al-equivalent normalized thicknesses of the electrode finger portion layers is defined as T_{IDT}[%] representing the Al-equivalent normalized thickness of the electrode finger portion, the Al-equivalent normalized thickness of the mass addition film is defined as Tₘ[%], and a value obtained by dividing a thickness ratio of the Al-equivalent normalized thickness Tₘ of the mass addition film relative to the Al-equivalent normalized thickness T_{IDT} of the electrode finger portion by about 3.15 is defined as T_{R} [%], T_{R}=(1/3.15)×(Tₘ/T_{IDT})×100 [%] is satisfied, and when a duty ratio of the IDT is denoted by d and a value obtained by dividing a dimension in the electrode finger portion extending direction of the mass addition film by the wavelength λ is defined as a wavelength ratio width W, the wavelength ratio width W of the mass addition film satisfies:

0.88×{0.0101×T_{IDT}²−0.1677×T_{IDT}+1.3201+0.4×(d−0.55)}≤W≤1.12×{0.0101×T_{IDT}²−0.1677×T_{IDT}+1.3201+0.4×(d−0.55)}, and the thickness ratio T_{R} satisfies 0.88×10.7≤T_{R}≤1.12×10.7.

An acoustic wave device according to another example embodiment of the present invention includes a high acoustic velocity material layer, a piezoelectric layer on the high acoustic velocity material layer and including lithium tantalate, and an interdigital transducer (IDT) on the piezoelectric layer and including multiple electrode finger portions each including at least one electrode finger portion layer, in which an acoustic velocity of a bulk wave that propagates in the high acoustic velocity material layer is higher than an acoustic velocity of an acoustic wave that propagates in the piezoelectric layer, when a direction of extension of the multiple electrode finger portions is defined as an electrode finger portion extending direction and when the IDT is viewed in a direction orthogonal or substantially orthogonal to the electrode finger portion extending direction, a region where adjacent electrode finger portions of the plurality of electrode finger portions overlap each other is an intersection region, and the intersection region includes a central region and a pair of edge regions sandwiching the central region in the electrode finger portion extending direction, the acoustic wave device further includes a mass addition film at at least one of the edge regions and continuously provided so as to overlap the multiple electrode finger portions and regions between the electrode finger portions in plan view, a resonant frequency is equal to or below about 1 GHz, when a wavelength defined by an electrode finger portion pitch of the IDT is denoted by λ, a value obtained by dividing a product of a density and a thickness of an arbitrary layer by a density of Al and the wavelength λ and expressed in percentage is defined as an Al-equivalent normalized thickness of the layer, a sum of the Al-equivalent normalized thicknesses of the electrode finger portion layers is defined as T_{IDT} [%] representing the Al-equivalent normalized thickness of the plurality of electrode finger portions, the Al-equivalent normalized thickness of the mass addition film is defined as Tₘ[%], and a value obtained by dividing a thickness ratio of the Al-equivalent normalized thickness Tₘ of the mass addition film relative to the Al-equivalent normalized thickness T_{IDT} of the plurality of electrode finger portions by about 3.15 is defined as T_{R} [%], T_{R}=(1/3.15)×(Tₘ/T_{IDT})×100 [%] is satisfied, and when a duty ratio of the IDT is denoted by d, a value obtained by dividing a dimension in the electrode finger portion extending direction of the mass addition film by the wavelength λ is defined as a wavelength ratio width W, a value x corresponds to a value of the wavelength ratio width W, and a value y corresponds to a value of the thickness ratio T_{R}, the wavelength ratio width W and the thickness ratio T_{R} have values within a range on an ellipse and inside of the ellipse on xy plane expressed by a Formula 3 and a Formula 4 defined below while setting a value t equal to or above about 0° and below about 360°:

$$x = 0.16 \times cos t \times cos ( 1.3 ° ) - 25.5 \times sin t \times sin ( 1.3 ° ) + 2.22 - 2.54 \times d + 2.06 \times {d}^{2} ; and \qquad ( Formula 3 )$$

$$0.16 \times cos t \times sin ( 1.3 ° ) + 25.5 \times cos t \times sin ( 1.3 ° ) + 25.5 - 0.033 \times ( {T}_{IDT} - 7.83 ) . \qquad ( Formula 4 )$$

An acoustic wave device according to another example embodiment of the present invention includes a high acoustic velocity material layer, a piezoelectric layer on the high acoustic velocity material layer and including lithium niobate, and an interdigital (IDT) on the piezoelectric layer and including multiple electrode finger portions each including at least one electrode finger portion layer, in which an acoustic velocity of a bulk wave that propagates in the high acoustic velocity material layer is higher than an acoustic velocity of an acoustic wave that propagates in the piezoelectric layer, when a direction of extension of the multiple electrode finger portions is defined as an electrode finger portion extending direction and when the IDT is viewed in a direction orthogonal or substantially orthogonal to the electrode finger portion extending direction, a region where adjacent electrode finger portions of the plurality of electrode finger portions overlap each other is an intersection region, and the intersection region includes a central region and a pair of edge regions sandwiching the central region in the electrode finger portion extending direction, the acoustic wave device further includes a mass addition film at at least one of the edge regions and continuously provided so as to overlap the multiple electrode finger portions and regions between the electrode finger portions in plan view, when a wavelength defined by an electrode finger portion pitch of the IDT is denoted by λ, a value obtained by dividing a product of a density and a thickness of an arbitrary layer by a density of Al and the wavelength λ and expressed in percentage is defined as an Al-equivalent normalized thickness of the layer, a sum of the Al-equivalent normalized thicknesses of the electrode finger portion layers is defined as T_{IDT} [%] representing the Al-equivalent normalized thickness of the plurality of electrode finger portions, the Al-equivalent normalized thickness of the mass addition film is defined as Tₘ[%], and a value obtained by dividing a thickness ratio of the Al-equivalent normalized thickness Tₘ of the mass addition film relative to the Al-equivalent normalized thickness T_{IDT} of the plurality of electrode finger portions by about 3.15 is defined as T_{R} [%], T_{R}=(1/3.15)×(Tₘ/T_{IDT})×100 [%] is satisfied, and when a duty ratio of the IDT is denoted by d, a value obtained by dividing a dimension in the electrode finger portion extending direction of the mass addition film by the wavelength λ is defined as a wavelength ratio width W, a value x corresponds to a value of the wavelength ratio width W, and a value y corresponds to a value of the thickness ratio T_{R}, the wavelength ratio width W and the thickness ratio T_{R} have values within a range on an ellipse and inside of the ellipse on xy plane expressed by a formula 5 and a formula 6 defined below while setting a value t equal to or above 0° and below 360°:

$$x = 0.22 \times cos t \times cos ( 6 ° ) - 3.9 \times sin t \times sin ( 6 ° ) + 1. + 0.4 \times ( d - 0.5 ) + 0.0022 \times ( {T}_{IDT} - 6.9 ) ; and \qquad ( Formula 5 )$$

$$y = 0.22 \times cos t \times sin ( 6 ° ) + 3.9 \times cos t \times sin ( 6 ° ) + 7.9 - 0.033 \times ( {T}_{IDT} - 6.9 ) . \qquad ( Formula 6 )$$

With acoustic wave devices according to example embodiments of the present invention, a transverse mode is more reliably reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to an example embodiment of the present invention.

FIG. 2 is a schematic cross-sectional view taken along the I-I line in FIG. 1.

FIG. 3 is a schematic cross-sectional view taken along the II-II line in FIG. 1.

FIG. 4 is a diagram showing a relationship between a wavelength ratio width W of a mass addition film and a thickness ratio T_{R} that results in a magnitude of a ripple attributed to a transverse mode being equal to about 1 dB or about 0.1 dB in a case where an Al-equivalent normalized thickness T_{IDT} of an electrode finger portion is equal to about 7.54% and a duty ratio d is equal to about 0.55.

FIG. 5 is a diagram showing a relationship between the wavelength ratio width W of the mass addition film and the thickness ratio T_{R} which results in the magnitude of the ripple attributed to the transverse mode being equal to about 1 dB or about 0.1 dB in a case where the Al-equivalent normalized thickness T_{IDT} of the electrode finger portion is equal to about 6.17% and the duty ratio d is equal to about 0.55.

FIG. 6 is a diagram showing a relationship between the wavelength ratio width W of the mass addition film and the thickness ratio T_{R} which results in the magnitude of the ripple attributed to the transverse mode being equal to about 1 dB or about 0.1 dB in a case where the Al-equivalent normalized thickness T_{IDT} of the electrode finger portion is equal to about 5.22% and the duty ratio d is equal to about 0.55.

FIG. 7 is a diagram showing a relationship between the wavelength ratio width W of the mass addition film and the thickness ratio T_{R} which results in the magnitude of the ripple attributed to the transverse mode being equal to about 1 dB or about 0.1 dB in a case where the Al-equivalent normalized thickness T_{IDT} of the electrode finger portion is equal to about 6.17% and the duty ratio d is equal to about 0.5.

FIG. 8 is a diagram showing a relationship between the wavelength ratio width W of the mass addition film and the thickness ratio T_{R} which results in the magnitude of the ripple attributed to the transverse mode being equal to about 1 dB or about 0.1 dB in a case where the Al-equivalent normalized thickness T_{IDT} of the electrode finger portion is equal to about 6.17% and the duty ratio d is equal to about 0.6.

FIG. 9A is a diagram showing that ripples develop in attenuation frequency characteristics of a filter device, FIG. 9B is a diagram showing impedance frequency characteristics of an acoustic wave resonator used in the filter device that exhibits the attenuation frequency characteristics according to FIG. 9A, and FIG. 9C is a diagram showing a return loss of the acoustic wave resonator that exhibits the impedance frequency characteristics according to FIG. 9B.

FIG. 10 is a diagram showing a relationship between a magnitude of a ripple as a return loss in a first acoustic wave resonator and a magnitude of a ripple in the attenuation frequency characteristics of the filter device.

FIG. 11 is a diagram showing a relationship between a magnitude of a ripple as a return loss in a second acoustic wave resonator and the magnitude of the ripple in the attenuation frequency characteristics of the filter device.

FIG. 12 is a diagram showing a relationship between the wavelength ratio width W of the mass addition film and the thickness ratio T_{R} which results in the magnitude of the ripple attributed to the transverse mode being equal to about 1 dB or about 0.3 dB in a case where a piezoelectric layer is made of lithium tantalate with a resonant frequency being equal to or below about 1 GHz and in a case where the Al-equivalent normalized thickness T_{IDT} of the electrode finger portion is equal to about 7.83% and the duty ratio d is equal to about 0.5.

FIG. 13 is a diagram showing a relationship between the wavelength ratio width W of the mass addition film and the thickness ratio T_{R} which results in the magnitude of the ripple attributed to the transverse mode being equal to about 1 dB or about 0.3 dB in the case where the piezoelectric layer is made of lithium tantalate with the resonant frequency being equal to or below 1 GHz and in a case where the Al-equivalent normalized thickness T_{IDT} of the electrode finger portion is equal to about 3.77% and the duty ratio d is equal to about 0.5.

FIG. 14 is a diagram showing a relationship between the wavelength ratio width W of the mass addition film and the thickness ratio T_{R} which results in the magnitude of the ripple attributed to the transverse mode being equal to about 1 dB or about 0.3 dB in the case where the piezoelectric layer is made of lithium tantalate with the resonant frequency being equal to or below 1 GHz and in a case where the Al-equivalent normalized thickness T_{IDT} of the electrode finger portion is equal to about 7.83% and the duty ratio d is equal to about 0.7.

FIG. 15A is a diagram showing that ripples develop in attenuation frequency characteristics of a low band filter device, FIG. 15B is a diagram showing impedance frequency characteristics of an acoustic wave resonator used in the filter device that exhibits the attenuation frequency characteristics according to FIG. 15A, and FIG. 15C is a diagram showing a return loss of the acoustic wave resonator that exhibits the impedance frequency characteristics according to FIG. 15B.

FIG. 16 is a diagram showing a relationship between the wavelength ratio width W of the mass addition film and the thickness ratio T_{R} which results in a magnitude of a ripple attributed to the transverse mode being equal to about 1 dB or about 0.2 dB in a case where a piezoelectric layer is made of lithium niobate and in a case where the Al-equivalent normalized thickness T_{IDT} of the electrode finger portion is equal to about 6.9% and the duty ratio d is equal to about 0.5.

FIG. 17 is a diagram showing a relationship between the wavelength ratio width W of the mass addition film and the thickness ratio T_{R} which results in the magnitude of the ripple attributed to the transverse mode being equal to about 1 dB or about 0.2 dB in the case where the piezoelectric layer is made of lithium niobate and in a case where the Al-equivalent normalized thickness T_{IDT} of the electrode finger portion is equal to about 13.7% and the duty ratio d is equal to about 0.5.

FIG. 18 is a diagram showing a relationship between the wavelength ratio width W of the mass addition film and the thickness ratio T_{R} which results in the magnitude of the ripple attributed to the transverse mode being equal to about 1 dB or about 0.2 dB in the case where the piezoelectric layer is made of lithium niobate and in a case where the Al-equivalent normalized thickness T_{IDT} of the electrode finger portion is equal to about 13.7% and the duty ratio d is equal to about 0.7.

### DETAILED DESCRIPTION OF THE EXAMPLE EMBODIMENTS

The present invention will be clarified below by explaining specific example embodiments of the present invention with reference to the drawings.

Respective example embodiments described in the present specification are merely exemplary, and partial replacement and combination of configurations between different example embodiments are possible.

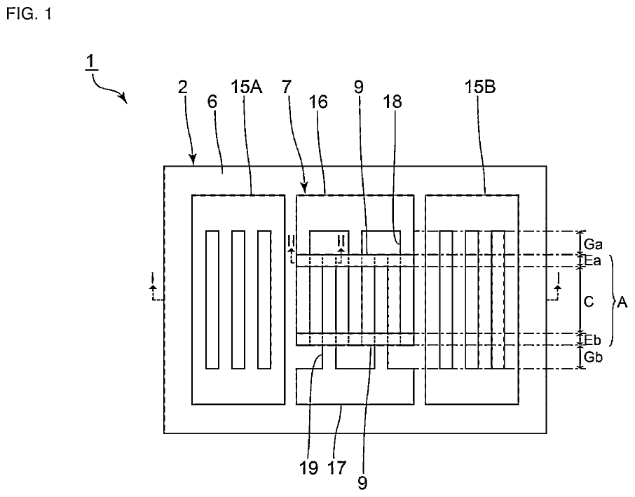

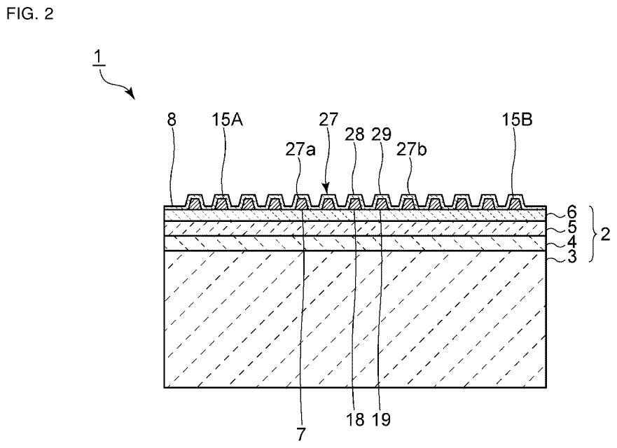

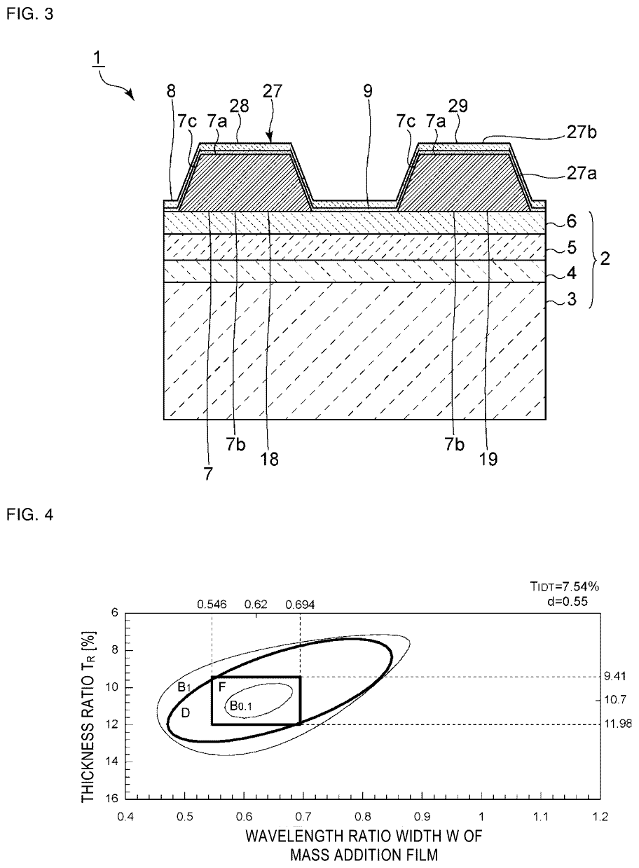

FIG. 1 is a schematic plan view of an acoustic wave device according to a first example embodiment of the present invention. FIG. 2 is a schematic cross-sectional view taken along the I-I line in FIG. 1. FIG. 3 is a schematic cross-sectional view taken along the II-II line in FIG. 1. Illustration of a dielectric film to be described later is omitted in FIG. 1.

As shown in FIGS. 1 and 2, an acoustic wave device 1 includes a piezoelectric substrate 2. As shown in FIG. 2, the piezoelectric substrate 2 includes a support substrate 3, a high acoustic velocity film 4 as a high acoustic velocity material layer, a low acoustic velocity film 5, and a piezoelectric layer 6. The high acoustic velocity film 4 is provided on the support substrate 3. The low acoustic velocity film 5 is provided on the high acoustic velocity film 4. The piezoelectric layer 6 is provided on the low acoustic velocity film 5. In the present example embodiment, the piezoelectric layer 6 is provided indirectly on the high acoustic velocity material layer with the low acoustic velocity film 5 interposed therebetween. However, the piezoelectric layer 6 may be provided directly on the high acoustic velocity material layer instead.

The piezoelectric layer 6 is made of lithium tantalate such as, for example, LiTaO₃. In the present specification, the expression “a certain member is made of a certain material” includes a case of including an impurity in an amount small enough to not substantially deteriorate electrical characteristics of the acoustic wave device. An interdigital transducer (IDT) electrode 7 is provided on the piezoelectric layer 6. An acoustic wave is excited by applying an alternating-current voltage to the IDT electrode 7.

The high acoustic velocity material layer in the piezoelectric substrate 2 is a layer having a relatively high acoustic velocity. To be more precise, an acoustic velocity of a bulk wave that propagates in the high acoustic velocity material layer is higher than an acoustic velocity of an acoustic wave that propagates in the piezoelectric layer 6. In the present example embodiment, the high acoustic velocity material layer is the high acoustic velocity film 4. On the other hand, the low acoustic velocity film 5 is a film having a relatively low acoustic velocity. To be more precise, an acoustic velocity of a bulk wave that propagates in the low acoustic velocity film 5 is lower than an acoustic velocity of a bulk wave that propagates in the piezoelectric layer 6.

As shown in FIG. 1, the IDT electrode 7 includes a first busbar 16, a second busbar 17, multiple first electrode fingers 18, and multiple second electrode fingers 19. The first busbar 16 and the second busbar 17 are opposed to each other. One end of each of the multiple first electrode fingers 18 is connected to the first busbar 16. One end of each of the multiple second electrode fingers 19 is connected to the second busbar 17. The multiple first electrode fingers 18 and the multiple second electrode fingers 19 are interdigitated with one another. The first electrode fingers 18 and the second electrode fingers 19 are connected to electric potentials that are different from each other.

As shown in FIG. 2, a dielectric film 8 is provided on the piezoelectric layer 6 to cover the IDT electrode 7. In the present example embodiment, for example, silicon oxide is used as a material of the dielectric film 8. Nonetheless, the material of the dielectric film 8 is not limited to this material.

An IDT 27 is formed by laminating the IDT electrode 7 and the dielectric film 8. A portion of the IDT electrode 7 where the first electrode fingers 18 and the dielectric film 8 are laminated defines a first electrode finger portion 28 in the IDT 27. A portion of the IDT electrode 7 where the second electrode fingers 19 and the dielectric film 8 are laminated defines a second electrode finger portion 29 in the IDT 27. In the following description, the first electrode finger portion 28 and the second electrode finger portion 29 of the IDT 27 may simply be described as the electrode finger portions in some cases. The first electrode fingers 18 and the second electrode fingers 19 of the IDT electrode 7 may simply be described as the electrode fingers in some cases.

Each electrode finger portion of the IDT 27 includes multiple electrode finger portion layers. The multiple electrode finger portion layers include a metallic layer 27a and a dielectric layer 27b. The metallic layer 27a is a layer included in the IDT electrode 7. To be more precise, the metallic layer 27a is a portion of the electrode fingers of the IDT electrode 7. Here, the IDT electrode 7 includes laminated metallic films in the present example embodiment. To be more precise, the IDT electrode 7 includes, for example, an Al layer and multiple Ti layers. For this reason, each electrode finger portion of the IDT 27 includes the multiple metallic layers 27a. Nonetheless, the material and the layer configuration of the IDT electrode 7 are not limited to those described above. The IDT electrode 7 may include one metallic layer. In this case, each electrode finger portion of the IDT 27 includes only one metallic layer 27a.

The dielectric layer 27b of the IDT 27 is a layer included in the dielectric film 8. The dielectric film 8 does not always have to be provided. In this case, the IDT 27 is the IDT electrode 7. Accordingly, each electrode finger portion layer may only include the metallic layer 27a. Each electrode finger portion only needs to include at least one electrode finger portion layer.

A pair of a reflector 15A and a reflector 15B are provided on the piezoelectric layer 6. When a direction of extension of the multiple electrode finger portions of the IDT 27 is defined as an electrode finger portion extending direction, the reflector 15A and the reflector 15B are opposed to each other in a direction orthogonal or substantially orthogonal to the electrode finger portion extending direction while sandwiching the IDT 27 therebetween. The direction orthogonal or substantially orthogonal to the electrode finger portion extending direction is parallel or substantially parallel to an acoustic wave propagating direction in the present example embodiment. The same material as that of the IDT electrode 7 can be used in each reflector. The acoustic wave device 1 of the present example embodiment is a surface acoustic wave resonator. For example, the acoustic wave device 1 can suitably be used in a mid-high band (MHB) filter device and the like. A frequency band of the mid-high band is, for example, in a range from about 1.7 GHz to about 2.7 GHz.

When the IDT 27 is viewed in the direction orthogonal or substantially orthogonal to the electrode finger portion extending direction, a region where the adjacent electrode finger portions overlap each other is an intersection region A shown in FIG. 1. The intersection region A includes a central region C and a pair of edge regions. To be more precise, the pair of edge regions include a first edge region Ea and a second edge region Eb. The first edge region Ea and the second edge region Eb are disposed so as to be opposed to each other in the electrode finger portion extending direction while sandwiching the central region C therebetween. The first edge region Ea is located on the first busbar 16 side. The second edge region Eb is located on the second busbar 17 side.

A pair of mass addition films 9 are provided at the pair of edge regions. To be more precise, one mass addition film 9 of the pair of mass addition films 9 is provided at the first edge region Ea. Another mass addition film 9 of the pair of mass addition films 9 is provided at the second edge region Eb. Each mass addition film 9 has a strip shape. To be more precise, each mass addition film 9 is continuously provided so as to overlap the multiple electrode finger portions and regions between the electrode finger portions in plan view. In the present specification, the plan view means a view of the acoustic wave device from a direction corresponding to an upper side in FIG. 2. For example, the dielectric film 8 side out of the piezoelectric layer 6 side and the dielectric film 8 is the upper side in FIG. 2.

As shown in FIG. 1, the acoustic velocity in each edge region is lower than the acoustic velocity in the central region C since each edge region is provided with the mass addition film 9. Accordingly, a low acoustic velocity region is provided in each edge region. Here, the low acoustic velocity region means a region where the acoustic velocity is lower than the acoustic velocity in the central region C.

The central region C and the pair of low acoustic velocity regions are arranged in this order from inside to outside in the electrode finger portion extending direction. Thus, a piston mode is provided so that the transverse mode can be reduced or prevented.

In the acoustic wave device 1, for example, tantalum oxide such as Ta₂O₅ is used as a material of the mass addition films 9. Nonetheless, the material of the mass addition films 9 is not limited to this material.

A cross-section in the first edge region Ea is shown in FIG. 3. In the first edge region Ea, the mass addition film 9 is provided between the IDT electrode 7 and the dielectric film 8. Although not illustrated, the mass addition film 9 is provided between the IDT electrode 7 and the dielectric film 8 in the second edge region Eb as well. Nevertheless, the IDT 27 does not include the mass addition film 9.

Each of the first electrode finger 18 and the second electrode finger 19 of the IDT electrode 7 includes a first surface 7a, a second surface 7b, and a side surface 7c. The first surface 7a and the second surface 7b are opposed to each other. Of the first surface 7a and the second surface 7b, the second surface 7b is located on the piezoelectric layer 6 side. The side surface 7c is connected to the first surface 7a and the second surface 7b. In the present example embodiment, the side surface 7c extends obliquely with respect to a normal direction to the second surface 7b. Nonetheless, the side surface 7c may extend parallel or substantially parallel to the normal line to the second surface 7b.

The dielectric film 8 is provided across the first surfaces 7a and the side surfaces 7c of the electrode fingers. Here, the dielectric film 8 is indirectly provided on the electrode fingers in each edge region with the mass addition film 9 interposed therebetween. The dielectric layer 27b in the electrode finger portion of the IDT 27 is assumed to be a portion that is directly or indirectly provided to the first surface 7a of the electrode finger in the dielectric film 8.

In the following description, a wavelength defined by an electrode finger portion pitch will be denoted by λ. The electrode finger portion pitch means a distance in the direction orthogonal or substantially orthogonal to the electrode finger portion extending direction between the centers of the electrode finger portions located adjacent to each other. A duty ratio of the IDT 27 will be denoted by d. Here, the duty ratio d of the IDT 27 is equal to the duty ratio of the IDT electrode 7. To be more precise, the duty ratio d of the IDT 27 is a duty ratio based on the second surface 7b of each electrode finger in the IDT electrode 7. A value obtained by dividing a dimension in the electrode finger portion extending direction of the mass addition film 9 by the wavelength λ will be defined as a wavelength ratio width W.

A value obtained by dividing a product of a density and a thickness of an arbitrary layer by a density of Al and the wavelength λ will be defined as an Al-equivalent normalized thickness of this layer. A sum of the Al-equivalent normalized thicknesses of the electrode finger portion layers will be defined as T_{IDT} [%] representing an Al-equivalent normalized thickness of the electrode finger portion. For example, n is assumed to be an arbitrary natural number, k is assumed to be a natural number that satisfies 1≤k≤n, and each electrode finger portion is assumed to have n layers of electrode finger portion layers. When a density of a k-th electrode finger portion layer from the piezoelectric layer 6 side is defined as ρₖ, a thickness thereof is defined as tₖ, an Al-equivalent normalized thickness thereof is defined as Tₖ[%], and a density of Al is defined as ρ_{Al}, the Al-equivalent normalized thickness Tₖ of each electrode finger portion layer is expressed as {(ρₖ·tₖ)/(ρ_{Al}−λ)}×100 [%]. Here, the value ρ_{Al} is equal to about 2.69 g/cm³ in the case of three significant digits. The Al-equivalent normalized thickness T_{IDT} of the electrode finger portion is expressed as T_{IDT}=Σ{(ρₖ·Tₖ)/(ρ_{Al}·λ)}×100 [%](1≤k≤n).

When the Al-equivalent normalized thickness of the mass addition film 9 is defined as Tₘ[%] and a value obtained by dividing a thickness ratio of the Al-equivalent normalized thickness Tₘ of the mass addition film 9 relative to the Al-equivalent normalized thickness T_{IDT} of the electrode finger portion by about 3.15 is defined as T_{R}[%], T_{R}=(1/3.15)×(Tₘ/T_{IDT})×100 [%] holds true. Here, to be more precise, the Al-equivalent normalized thickness Tₘ of the mass addition film 9 corresponds to a value obtained by assigning the density and the thickness of the mass addition film 9 to a density Pₖ and a thickness tₖ in the expression {(ρₖ·tₖ)/(ρ_{Al}−λ)}×100 that represents the Al-equivalent normalized thickness Tₖ of the electrode finger portion layer. The above-described value “about 3.15” represents a ratio of a density ρ_{Ta2O5} of tantalum oxide relative to the density ρ_{Al} of Al. That is to say, ρ_{Ta2O5}/ρ_{Al}=about 3.15 is satisfied.

The acoustic wave device 1 of the present example embodiment includes at least one set of first characteristics and second characteristics. Here, a relationship between the wavelength ratio width W and the thickness ratio T_{R} will be expressed on xy plane. To be more precise, on the xy plane, a value x is assumed to correspond to a value of the wavelength ratio width W, and a value y is assumed to correspond to a value of the thickness ratio T_{R}. The first characteristics are as follows: 1) the piezoelectric layer 6 is made of lithium tantalate; 2) a resonant frequency of the acoustic wave device 1 is higher than 1 GHz; and 3) the wavelength ratio width W and the thickness ratio T_{R} fall within a range on an ellipse and inside of the ellipse expressed by the following formula 1 and formula 2 while setting a value θ equal to or above 0° and below 360°.

$$x = 0.19 \times cos ( - 5.5 ° ) \times cos θ - 0.021 \times sin ( - 5.5 ° ) \times sin θ + 0.0146 \times {T}_{IDT}^{2} - 0.229 \times {T}_{IDT} + 1.5611 + 0.4 \times ( d - 0.55 ) \qquad Formula 1$$

$$y = 0.19 \times sin ( - 5.5 ° ) \times cos θ + 0.021 \times cos ( - 5.5 ° ) \times sin θ + 10.15 \qquad Formula 2$$

The second characteristics are as follows: 1) the piezoelectric layer 6 is made of lithium tantalate; 2) the resonant frequency of the acoustic wave device 1 is higher than 1 GHz; and 3) the wavelength ratio width W of the mass addition film 9 and the thickness ratio T_{R} fall within a range on the following range. Specifically, the wavelength ratio width W satisfies 0.88×{0.0101×T_{IDT}²−0.1677×T_{IDT}+1.3201+0.4×(d−0.55)}≤W≤1.12×{0.010×T_{IDT}²−0.1677×T_{IDT}+1.3201+0.4×(d−0.55)}. The thickness ratio T_{R} satisfies 0.88×10.7≤T_{R}≤1.12×10.7.

Since the acoustic wave device 1 includes at least one set of the first characteristics and the second characteristics, the acoustic wave device 1 can more reliably reduce or prevent the transverse mode. To be more precise, in the acoustic wave device 1, the magnitude of the ripple attributed to the transverse mode in the frequency characteristics can more reliably be reduced to equal to or below about 1 dB. Details of this feature will be described below.

The transverse mode includes various modes from first to eleventh orders, for example. According to the present invention, the magnitude of the largest ripple among the ripples attributed to the transverse modes in the frequency characteristics can more reliably be reduced to equal to or below about 1 dB.

The inventors of example embodiments of the present invention have discovered that the transverse mode can be reduced or prevented by setting the relationship between the value T_{R} obtained by dividing the thickness ratio of the Al-equivalent normalized thickness Tₘ of the mass addition film 9 relative to the Al-equivalent normalized thickness T_{IDT} of the electrode finger portion by about 3.15 and the wavelength ratio width W of the mass addition film 9 to a prescribed relationship. The inventors have derived the relationship between the wavelength ratio width W and the thickness ratio T_{R} and the range thereof with which the magnitude of the ripple attributed to the transverse mode in the frequency characteristics can be reduced to equal to or below about 1 dB in the acoustic wave device. Design parameters of the acoustic wave device concerning this derivation have been determined as follows:
Piezoelectric layer; material . . . LiTaO₃,
Metallic layers of IDT; layer structure . . . Ti layer/Al layer/Ti layer from piezoelectric layer side, thicknesses . . . t₁=12 nm/t₂=about 100 nm/t₃=about 4 nm from piezoelectric layer side,
Dielectric layer of IDT; material . . . SiO₂, thickness . . . t₅=about 30 nm,
Dielectric film; material . . . SiO₂, thickness . . . about 30 nm,
Wavelength λ . . . about 1.8 μm, about 2.2 μm, or about 2.6 μm,
Duty ratio d . . . about 0.5, about 0.55, or about 0.6,
Al-equivalent normalized thickness T_{IDT} of electrode finger portion . . . about 5.22%, about 6.17%, or about 7.54%,
Material of mass addition film; Ta₂O₅,
Wavelength ratio width W of mass addition film; changed in increments of about 0.02 in a range from equal to or above about 0.4 to equal to or below about 1.1, and
Thickness ratio T_{R}; changed in increments of about 0.2% in a range from equal to or above about 6.5% to equal to or below about 14.5%.

The thickness ratio T_{R} was changed as described above by changing the thickness of the mass addition film depending on the Al-equivalent normalized thickness T_{IDT}. A return loss was measured every time the thickness ratio T_{R} and the wavelength ratio width W were changed, and the magnitude of the ripple attributed to the transverse mode was thus obtained.

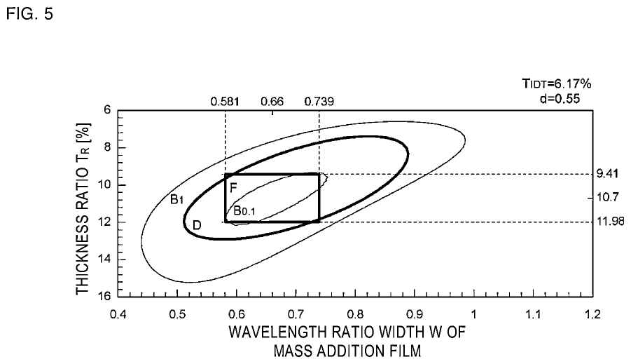

FIG. 4, for example, is a diagram showing the relationship between the wavelength ratio width W of the mass addition film and the thickness ratio T_{R} that results in the magnitude of the ripple attributed to the transverse mode being equal to about 1 dB or about 0.1 dB in a case where the Al-equivalent normalized thickness T_{IDT} of the electrode finger portion is equal to about 7.54% and the duty ratio d is equal to about 0.55. In FIG. 4, the value x on the xy plane corresponds to the value of the wavelength ratio width W and the value y thereon corresponds to the value of the thickness ratio T_{R}. The same applies to FIGS. 5 to 8 to be described later.

In FIG. 4, combinations of the wavelength ratio width W and the thickness ratio T_{R} that result in the magnitude of the ripple attributed to the transverse mode being equal to about 1 dB in the frequency characteristics of the acoustic wave device are plotted with a solid line B₁. The magnitude of the ripple attributed to the transverse mode becomes equal to or below about 1 dB in the case of the combination of the wavelength ratio width W and the thickness ratio T_{R} within a range surrounded by the solid line B₁.

An ellipse D expressed by the formula 1 and the formula 2 is plotted in FIG. 4. This ellipse D is located within the range surrounded by the solid line B₁. Moreover, the wavelength ratio width W and the thickness ratio T_{R} having the values on the ellipse D and within the range inside the ellipse D represent the above-described first characteristics. Accordingly, the magnitude of the ripple attributed to the transverse mode can more reliably be reduced to equal to or below about 1 dB since the acoustic wave device 1 has the first characteristics.

Nevertheless, the conditions to result in the magnitude of the ripple attributed to the transverse mode being equal to or below about 1 dB vary when the Al-equivalent normalized thickness T_{IDT} of the electrode finger portion and the duty ratio d are different. Given the circumstances, the Al-equivalent normalized thickness T_{IDT} of the electrode finger portion and the duty ratio d were changed, and the conditions resulting in the magnitude of the ripple attributed to the transverse mode being equal to or below about 1 dB were desired regarding the respective cases. The ellipse D expressed by the formula 1 and the formula 2 is the ellipse thus derived. As a consequence, the magnitude of the ripple attributed to the transverse mode can be set equal to or below about 1 dB in any case of the Al-equivalent normalized thickness T_{IDT} of the electrode finger portion and the duty ratio d as long as the wavelength ratio width W and the thickness ratio T_{R} have the values on the ellipse D and within the range inside the ellipse D.

FIG. 4 plots a range F. This range F is located within the range surrounded by the solid line B₁. Moreover, the wavelength ratio width W and the thickness ratio T_{R} having the values within this range F represent the second characteristics. Accordingly, the magnitude of the ripple attributed to the transverse mode can more reliably be reduced to equal to about 1 or below dB since the acoustic wave device 1 has the second characteristics.

To be more precise, for example, the range F is a range of about ±12% centered on the combination of the wavelength ratio width W and the thickness ratio T_{R} with which the transverse mode is suppressed most. The wavelength ratio width W and the thickness ratio T_{R} with which the transverse mode is suppressed most vary depending on the Al-equivalent normalized thickness T_{IDT} of the electrode finger portion and on the duty ratio d. Accordingly, the Al-equivalent normalized thickness T_{IDT} of the electrode finger portion and the duty ratio d were changed, and the wavelength ratio width W and the thickness ratio T_{R} with which the ripple attributed to the transverse mode is reduced or prevented most were desired regarding the respective cases.

The wavelength ratio width W in the range F thus derived satisfies 0.88×{0.0101×T_{IDT}²−0.1677×T_{IDT}+1.3201+0.4×(d−0.55)}≤W≤1.12×{0.0101×T_{IDT}²−0.1677×T_{IDT}+1.3201+0.4×(d−0.55)}. The thickness ratio T_{R} derived as described above satisfies 0.88×10.7≤T_{R}≤1.12×10.7, which defines a certain range. Accordingly, the magnitude of the ripple attributed to the transverse mode can be set equal to or below about 1 dB in any case of the Al-equivalent normalized thickness T_{IDT} of the electrode finger portion and on the duty ratio d since the wavelength ratio width W and the thickness ratio T_{R} fall within the range F.

Here, in FIG. 4, combinations of the wavelength ratio width W and the thickness ratio T_{R} that result in the magnitude of the ripple attributed to the transverse mode being equal to about 0.1 dB are plotted with a solid line B_{0.1}. The magnitude of the ripple attributed to the transverse mode can be suppressed equal to or below about 0.1 dB by setting the values of the wavelength ratio width W and the thickness ratio T_{R} within a range surrounded by the solid line B_{0.1}. As shown in FIG. 4, when the wavelength ratio width W of the mass addition film 9 and the thickness ratio T_{R} fall within the range F, the wavelength ratio width W and the thickness ratio T_{R} are either values close to the solid line B_{0.1} or values within a range surrounded by the solid line B_{0.1}. Accordingly, the transverse mode can be suppressed more reliably and effectively when the acoustic wave device 1 has the second characteristics.

FIGS. 5 to 8 show cases where the Al-equivalent normalized thickness T_{IDT} of the electrode finger portion and the duty ratio d have conditions different from those in FIG. 4. FIGS. 5 to 8 also plot the solid line B₁, the solid line B_{0.1}, the ellipse D, and the range F.

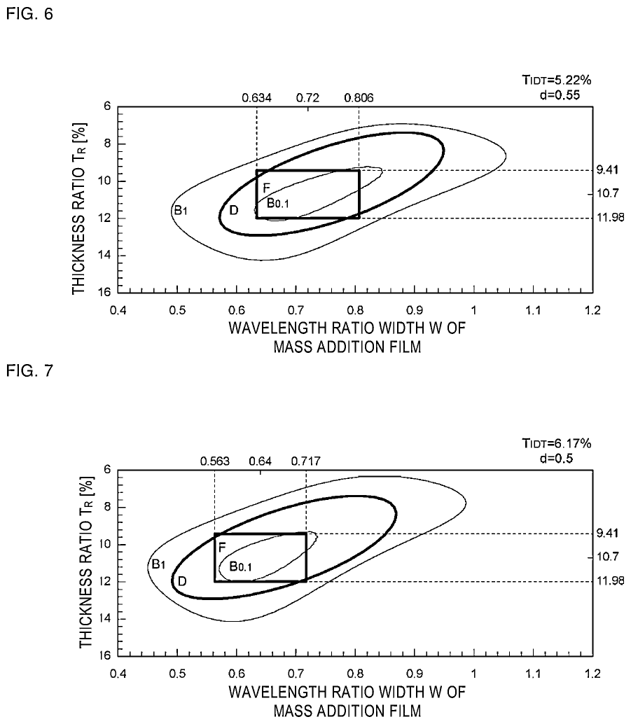

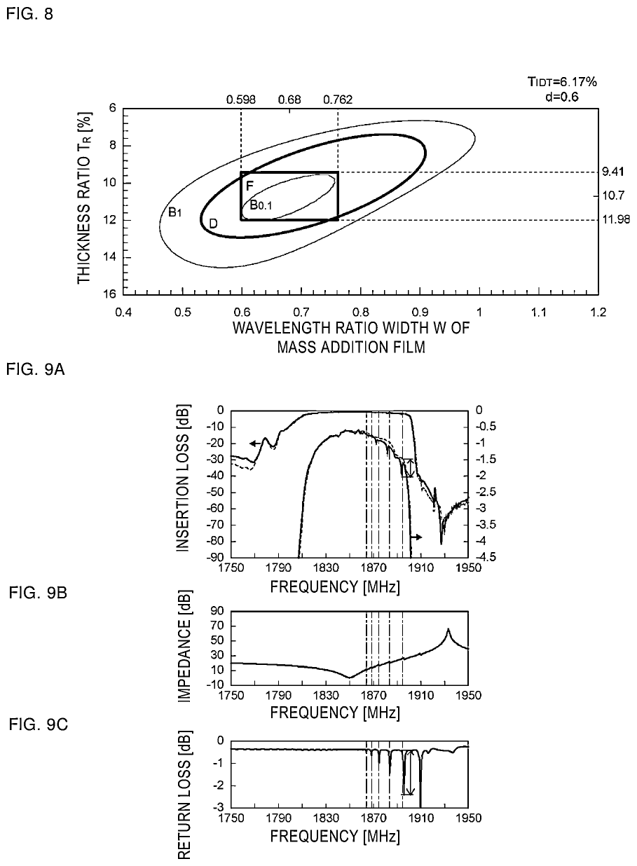

FIG. 5 is a diagram showing a relationship between the wavelength ratio width W of the mass addition film and the thickness ratio T_{R} which results in the magnitude of the ripple attributed to the transverse mode being equal to about 1 dB or about 0.1 dB in a case where the Al-equivalent normalized thickness T_{IDT} of the electrode finger portion is equal to about 6.17% and the duty ratio d is equal to about 0.55. FIG. 6 is a diagram showing a relationship between the wavelength ratio width W of the mass addition film and the thickness ratio T_{R} which results in the magnitude of the ripple attributed to the transverse mode being equal to about 1 dB or about 0.1 dB in a case where the Al-equivalent normalized thickness T_{IDT} of the electrode finger portion is equal to about 5.22% and the duty ratio d is equal to about 0.55. FIG. 7 is a diagram showing a relationship between the wavelength ratio width W of the mass addition film and the thickness ratio T_{R} which results in the magnitude of the ripple attributed to the transverse mode being equal to about 1 dB or about 0.1 dB in a case where the Al-equivalent normalized thickness T_{IDT} of the electrode finger portion is equal to about 6.17% and the duty ratio d is equal to about 0.5. FIG. 8 is a diagram showing a relationship between the wavelength ratio width W of the mass addition film and the thickness ratio T_{R} which results in the magnitude of the ripple attributed to the transverse mode being equal to about 1 dB or about 0.1 dB in a case where the Al-equivalent normalized thickness T_{IDT} of the electrode finger portion is equal to about 6.17% and the duty ratio d is equal to about 0.6.

As shown in FIGS. 5 to 8, the wavelength ratio width W of the mass addition film 9 as the value x and the thickness ratio T_{R} as the value y have the values on the ellipse D and within the range inside the ellipse D. Accordingly, the magnitude of the ripple attributed to the transverse mode can more reliably be reduced to equal to or below about 1 dB. As described above, the ellipse D is the ellipse expressed by the formula 1 and formula 2 while setting the value θ equal to or above about 0° and below about 360°.

In the meantime, the wavelength ratio width W and the thickness ratio T_{R} having the values within the range F can more reliably reduce or prevent the magnitude of the ripple attributed to the transverse mode equal to or below 1 dB. To be more precise, the wavelength ratio width W only needs to satisfy 0.88×{0.0101×T_{IDT}²−0.1677×T_{IDT}+1.3201+0.4×(d−0.55)}≤W≤1.12×{0.0101×T_{IDT}²−0.1677×T_{IDT}+1.3201+0.4×(d−0.55)}. The thickness ratio T_{R} only needs to satisfy about 0.88×10.7≤T_{R}≤about 1.12×10.7.

Here, regarding the conditions shown in FIGS. 4 to 8, the transverse mode is reduced or prevent most when the wavelength ratio width W of the mass addition film 9 and the thickness ratio T_{R} have the following values. The range F was derived from these results:

T_{IDT}=about 7.54%, d=about 0.55; W=about 0.62, T_{R}=about 10.7%,

T_{IDT}=about 6.17%, d=about 0.55; W=about 0.66, T_{R}=about 10.7%,

T_{IDT}=about 5.22%, d=about 0.55; W=about 0.72, T_{R}=about 10.7%,

T_{IDT}=about 6.17%, d=about 0.5; W=about 0.64, T_{R}=about 10.7%, and

T_{IDT}=about 6.17%, d=about 0.6; W=about 0.68, T_{R}=about 10.7%.

Acoustic wave devices according to example embodiments of the present invention are used as an acoustic wave resonator of a filter device, for example. The acoustic wave device 1 of the present example embodiment can more reliably reduce or prevent the transverse mode. Accordingly, the ripple in the frequency characteristics of the filter device can be more reliably reduced or prevented. Details of this feature will be described below.

FIG. 9A is a diagram showing that ripples develop in attenuation frequency characteristics of the filter device. FIG. 9B is a diagram showing impedance frequency characteristics of the acoustic wave resonator used in the filter device having the attenuation frequency characteristics according to FIG. 9A. FIG. 9C is a diagram showing a return loss of the acoustic wave resonator having the impedance frequency characteristics according to FIG. 9B.

As shown in FIG. 9A, multiple ripples develop in the attenuation frequency characteristics of the filter device. Here, the multiple ripples develop in a pass band of the filter device. At the frequencies in which these ripples develop, the ripples also develop in the impedance frequency characteristics of the acoustic wave resonator as shown in FIG. 9B. Accordingly, unnecessary waves generated in the acoustic wave resonator used in the filter device cause the ripples to develop in the attenuation frequency characteristics of the filter device. Here, the multiple unnecessary waves plotted in FIG. 9B represent the transverse modes. When a ripple attributed to a transverse mode as a return loss of the acoustic wave resonator shown in FIG. 9C is larger, the ripple in the filter device shown in FIG. 9A becomes larger.

Relationships of the ripples in the frequency characteristics between the acoustic wave resonator and the filter device will be described below in more detail. Multiple acoustic wave resonators and multiple filter devices were prepared. Regarding each of the acoustic wave resonators, the magnitude of the ripple attributed to the transverse mode as the return loss was adjusted. Thus, the magnitudes of the ripples were made different from one another among the respective acoustic wave resonators. Each filter device includes one of these acoustic wave resonators and another one of the acoustic wave resonators. Here, the acoustic wave resonators with the adjusted magnitudes of the ripples were arranged in two ways in the filter device. In the following description, the acoustic wave resonator arranged in one way will be defined as a first acoustic wave resonator. The acoustic wave resonator in another way will be defined as a second acoustic wave resonator. To be more precise, the first acoustic wave resonator is a serial arm resonator in the filter device. The second acoustic wave resonator is a parallel arm resonator in the filter device.

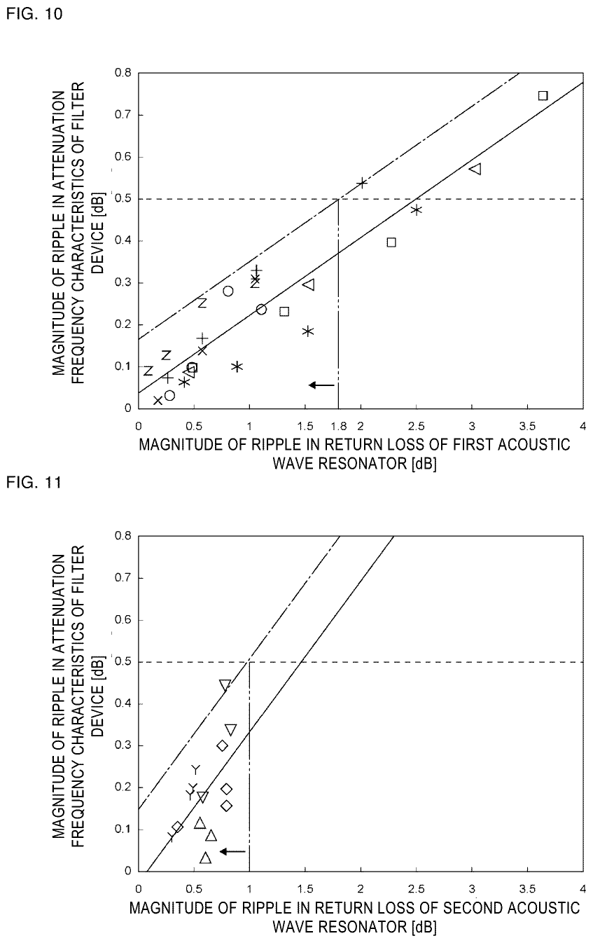

FIG. 10 is a diagram showing a relationship between a magnitude of a ripple as a return loss in the first acoustic wave resonator and a magnitude of a ripple in the attenuation frequency characteristics of the filter device. FIG. 11 is a diagram showing a relationship between a magnitude of a ripple as a return loss in the second acoustic wave resonator and the magnitude of the ripple in the attenuation frequency characteristics of the filter device.

Each plot in FIG. 10 shows the relationship between the magnitude of the ripple in the return loss of each first acoustic wave resonator and the magnitude of the ripple in the attenuation frequency characteristics of each filter device. Based on these plots, the relationship of the magnitude of the ripple in the frequency characteristics between the first acoustic wave resonator and the filter device was derived. This relationship is shown with a solid straight line in FIG. 10.

On the other hand, a dash-dotted straight line in FIG. 10 is a straight line having the same or substantially the same inclination as that of the solid straight line in a case where the straight line passes through any of the plots and maximizes an intercept. The dash-dotted straight line shows a relationship assumed to maximize the ripple in the attenuation frequency characteristics of the filter device relative to the ripple as the return loss in the first acoustic wave resonator.

Here, in the filter device, the magnitude of the ripple often needs to be, for example, equal to or below about 0.5 dB. According to the relationship shown with the dash-dotted straight line in FIG. 10, for example, the magnitude of the ripple in the attenuation frequency characteristics of the filter device can be set equal to or below about 0.5 dB by setting the magnitude of the ripple as the return loss in the first acoustic wave resonator equal to or below about 1.8 dB.

Meanwhile, a solid straight line in FIG. 11 shows the relationship between the magnitudes of the ripples of the second acoustic wave resonator and in the frequency characteristics of the filter device. An inclination of the solid straight line in FIG. 11 is larger than the inclination of the solid straight line in FIG. 10. As described above, the relationship of the magnitudes of the acoustic wave resonator and the filter device varies depending on the layout of the acoustic wave resonator ant the like. A dash-dotted straight line in FIG. 11 shows a relationship assumed to maximize the ripple in the attenuation frequency characteristics of the filter device relative to the ripple as the return loss in the second acoustic wave resonator. According to the relationship shown by this dash-dotted straight line, for example, the magnitude of the ripple in the attenuation frequency characteristics of the filter device can be set equal to or below about 0.5 dB by setting the magnitude of the ripple as the return loss in the second acoustic wave resonator equal to or below about 1 dB.

As described above, the magnitude of the ripple in the attenuation frequency characteristics of the filter device can more reliably be reduced to equal to or below about 0.5 dB by setting the magnitude of the ripple in the frequency characteristics of the acoustic wave device, which is used as the acoustic wave resonator in the filter device, equal to or below about 1 dB. As described above, in the present example embodiment, the magnitude of the ripple attributed to the transverse mode can more reliably be reduced to equal to or below about 1 dB. Accordingly, in the case where the acoustic wave device 1 is used in the filter device, the ripple in the attenuation frequency characteristics of the filter device can more reliably be reduced to equal to or below about 0.5 dB as well. It is therefore possible to reduce or prevent deterioration of filter characteristics of the filter device.

More detailed configurations of the present example embodiment will be described below. As shown in FIG. 1, in the present example embodiment, a pair of gap regions are disposed between the intersection region A and the pair of busbars. Specifically, the pair of gap regions include a first gap region Ga and a second gap region Gb. The first gap region Ga is located on the first busbar 16 side. The second gap region Gb is located on the second busbar 17 side.

Of the multiple first electrode fingers 18 and the multiple second electrode fingers 19, only the multiple first electrode fingers 18 are provided in the first gap region Ga. Thus, a high acoustic velocity region is provided in the first gap region Ga. The high acoustic velocity region is a region where an acoustic velocity therein is higher than an acoustic velocity in the central region C. A high acoustic velocity region is also provided in the second gap region Gb likewise.

The central region C, the pair of low acoustic velocity regions, and the pair of high acoustic velocity regions are arranged in this order from the inside to the outside in the electrode finger portion extending direction. Thus, the transverse mode can be reduced or prevented even more reliably.

In the present example embodiment, each mass addition film 9 is provided in each edge region. Here, the mass addition film 9 only needs to be provided to at least one of the first edge region Ea and the second edge region Eb. Nevertheless, the mass addition films 9 are preferably provided to both of the first edge region Ea and the second edge region Eb. Thus, the transverse mode can be reduced or prevented more reliably and effectively.

As shown in FIG. 3, the mass addition film 9 is provided between the IDT electrode 7 and the dielectric film 8. Nonetheless, the mass addition film 9, the IDT electrode 7, and the dielectric film 8 may be laminated in this order from the piezoelectric layer 6 side, for example. Alternatively, the IDT electrode 7, the dielectric film 8, and the mass addition film 9 may be laminated in this order from the piezoelectric layer 6 side.

As shown in FIG. 2, the piezoelectric substrate 2 of the acoustic wave device 1 is a laminated substrate. Examples of materials of respective layers in the piezoelectric substrate 2 are described below.

In the present example embodiment, for example, lithium tantalate such as LiTaO₃ is used as the material of the piezoelectric layer 6.

A dielectric body such as, for example, glass, silicon oxide, silicon oxynitride, lithium oxide, tantalum oxide, a compound prepared by adding fluorine, carbon or boron to silicon oxide, or a material including any of the above-described materials as a principal component can be used as the material of the low acoustic velocity film 5. In the present specification, the principal component means a component having a proportion in excess of 50 wt %. The material of the principal component may be present in any of, for example, single-crystal, polycrystalline, and amorphous states or in a mixture of these states.

As described above, in the present example embodiment, the high acoustic velocity material layer is the high acoustic velocity film 4. A piezoelectric body such as aluminum nitride, lithium tantalate, lithium niobate, and quartz, a ceramic such as alumina, sapphire, magnesia, silicon nitride, silicon carbide, zirconia, cordierite, mullite, steatite, forsterite, spinel, and SiALON, a dielectric body such as aluminum oxide, silicon oxynitride, DLC (diamond-like carbon), and diamond, a semiconductor such as silicon, and a material including any of the above-described materials as a principal component can also be used as the material of the high acoustic velocity material, for example. An aluminum compound including oxygen and one or more elements of, for example Mg, Fe, Zn, Mn, or the like is included in the spinel. MgAl₂O₄, FeAl₂O₄, ZnAl₂O₄, and MnAl₂O₄ are examples of the spinel.

A piezoelectric body such as, for example, aluminum nitride, lithium tantalate, lithium niobate, and quartz, a ceramic such as alumina, sapphire, magnesia, silicon nitride, silicon carbide, zirconia, cordierite, mullite, steatite, and forsterite, a dielectric body such as diamond and glass, a semiconductor such as silicon and gallium nitride, a resin, and a material including any of the above-described materials as a principal component can be used as the material of the support substrate 3.

In the piezoelectric substrate 2, the high acoustic velocity film 4 as the high acoustic velocity material layer, the low acoustic velocity film 5, and the piezoelectric layer 6 are laminated in this order. Thus, it is possible to effectively confine energy of the acoustic wave on the piezoelectric layer 6 side.

The lamination structure of the piezoelectric substrate is not limited to the above-described structure. For example, the piezoelectric substrate may be a laminated substrate including the support substrate, the high acoustic velocity film, and the piezoelectric layer. Alternatively, the high acoustic velocity material layer may be a high acoustic velocity support substrate. In this case, for example, the piezoelectric substrate may be a laminated substrate including the high acoustic velocity support substrate, the low acoustic velocity film, and the piezoelectric layer, or a laminated substrate including the high acoustic velocity support substrate and the piezoelectric layer. It is possible to effectively confine the energy of the acoustic wave on the piezoelectric layer side in these cases as well.

Examples of metallic materials and dielectric materials as well as densities of the respective materials are shown on Table 1. Metals listed on Table 1 may be used as the material of the metallic layer 27a in the IDT 27 shown in FIG. 3. Dielectric bodies listed on Table 1 may be used as the material of the dielectric layer 27b. Moreover, the dielectric bodies listed on Table 1 may be used in the mass addition film 9. The metallic materials used in the metallic layer 27a and the dielectric materials used in the dielectric layer 27b or the mass addition film 9 may include a small amount of different material. For example, the Al layer may include a small amount of Cu.

TABLE 1

| | Density [g/cm³] |
|---|---|
| Al | 2.694 |
| Ti | 4.54 |
| Cu | 8.93 |
| Ta | 16.67 |
| Au | 19.3 |
| Pt | 21.37 |
| Aluminum oxide | 3.98 |
| Silicon oxide | 2.21 |
| Germanium oxide | 6.2 |
| Tantalum oxide | 8.47 |

The density of the material of the mass addition film 9 is preferably higher than the density of the dielectric layer 27b of the electrode finger portion. Thus, it is possible to set the thickness of the mass addition film 9 smaller than the thickness of the dielectric film 8. Accordingly, the mass addition film 9 can be more reliably covered with the dielectric film 8.

For example, the frequency of the acoustic wave device 1 can be adjusted by trimming a surface of the dielectric film 8 and adjusting the thickness of the dielectric film 8. In the above-described configuration, the mass addition film 9 can be more reliably covered with the dielectric film 8. Accordingly, it is possible to keep the mass addition film 9 from being trimmed in the course of trimming the dielectric film 8. Thus, it is possible to reduce or prevent an influence by trimming on a difference between the acoustic velocity in the central region C shown in FIG. 1 and the acoustic velocity in the pair of edge regions. Accordingly, the transverse mode can be favorably reduced or prevented.

When a dimension in the electrode finger portion extending direction of the intersection region A is defined as an intersection width, the intersection width is, for example, preferably equal to or above about 10λ. In this case, the transverse mode can be reduced or prevented more reliably and favorably. The intersection width is, for example, preferably equal to or below about 30λ. Thus, it is possible to reduce or prevent an increase in size of the acoustic wave device 1.

In the example shown in FIG. 1, end edge portions on the first busbar 16 side of the mass addition film 9 located in the first edge region Ea overlap tip ends of the second electrode fingers 19 in plan view. Nonetheless, the end edge portions on the first busbar 16 side of the mass addition film 9 located in the first edge region Ea do not have to overlap the tip ends of the second electrode fingers 19 in plan view. In this case, the end edge portions on the first busbar 16 side of the mass addition film 9 only need to be located in the first edge region Ea. To be more precise, a distance in the electrode finger portion extending direction between the end edge portions on the first busbar 16 side of the mass addition film 9 located in the first edge region Ea and the tip ends of the second electrode fingers 19 in plan view is, for example, preferably equal to or below about 0.1λ.

In the example shown in FIG. 1, end edge portions on the second busbar 17 side of the mass addition film 9 located in the second edge region Eb overlap tip ends of the first electrode fingers 18 in plan view. Nonetheless, the end edge portions on the second busbar 17 side of the mass addition film 9 located in the second edge region Eb do not have to overlap the tip ends of the first electrode fingers 18 in plan view. In this case, the end edge portions on the second busbar 17 side of the mass addition film 9 only need to be located in the second edge region Eb. To be more precise, a distance in the electrode finger portion extending direction between the end edge portions on the second busbar 17 side of the mass addition film 9 located in the second edge region Eb and the tip ends of the first electrode fingers 18 in plan view is, for example, preferably equal to or below about 0.1λ.

Here, the respective preferred configurations, the configuration of the piezoelectric substrate, the configuration of the mass addition film, and the configuration of the IDT discussed in the description of the first example embodiment are also applicable to configurations of example embodiments of the present invention other than the first example embodiment.

Here, as a result of intensive studies conducted by the inventors of example embodiments of the present invention, it has been clarified that the relations between the thickness of the electrode finger portion and the duty ratio as well as between the wavelength ratio width W of the mass addition film and the thickness ratio T_{R}, which can suppress the transverse mode, vary depending on the resonant frequency of the acoustic wave device and on the material of the piezoelectric layer.

As described above, in the first example embodiment, the piezoelectric layer 6 is made of, for example, lithium tantalate. Moreover, the resonant frequency of the acoustic wave device 1 is, for example, higher than about 1 GHz. In this case, the wavelength ratio width W and the thickness ratio T_{R} only need to have the values within the range on the ellipse and the inside of the ellipse expressed by the above-described formula 1 and formula 2 while setting the value θ equal to or above about 0° and below about 360°. Alternatively, the wavelength ratio width W and the thickness ratio T_{R} only need to fall within the range F. Thus, the transverse mode can reliably be reduced or prevented.

Moreover, examples in a case where the piezoelectric layer is made of lithium tantalate and the resonant frequency of the acoustic wave device is equal to or below about 1 GHz and in a case where the piezoelectric layer is made of lithium niobate will be discussed below in a second example embodiment and a third example embodiment of the present invention. Lamination structures in the second example embodiment and the third example embodiment are the same or substantially the same as the lamination structure in the first example embodiment. For this reason, the reference signs and the drawings used in the description of the first example embodiment will be incorporated in the description of the second example embodiment and the third example embodiment.

The second example embodiment is different from the first example embodiment in that the resonant frequency of the acoustic wave device is equal to or below about 1 GHz. An acoustic wave device of the second example embodiment includes the piezoelectric substrate 2 and the IDT 27, which are shown by incorporating FIG. 2. Here, the piezoelectric substrate 2 only needs to include at least the high acoustic velocity material layer and the piezoelectric layer 6. As shown by incorporating FIG. 1, the mass addition films 9 are provided in the first edge region Ea and the second edge region Eb, respectively. Nonetheless, the mass addition film 9 only needs to be provided in at least one of the first edge region Ea and the second edge region Eb.

The piezoelectric layer 6 is made of lithium tantalate such as LiTaO₃, for example. For example, the acoustic wave device of the second example embodiment can suitably be used in a low band (LB) filter device and the like.

The second example embodiment has the following features: 1) the piezoelectric layer 6 is made of lithium tantalate; 2) the resonant frequency of the acoustic wave device is equal to or below about 1 GHz; and 3) the wavelength ratio width W and the thickness ratio T_{R} have values within a range on an ellipse and inside of the ellipse expressed by the following formula 3 and formula 4 while setting a value t equal to or above about 0° and below about 360°. Here, the value t in the formula 3 and the formula 4 represents an angle and is different from the above-described thickness tₖ.

$$x = 0.16 \times cos t \times cos ( 1.3 ° ) - 25.5 \times sin t \times sin ( 1.3 ° ) + 2.22 - 2.54 \times d + 2.06 \times {d}^{2} \qquad Formula 3$$

$$y = 0.16 \times cos t \times sin ( 1.3 ° ) + 25.5 \times cos t \times sin ( 1.3 ° ) + 25.5 - 0.033 \times ( {T}_{IDT} - 7.83 ) \qquad Formula 4$$

To be more precise, the inventors of example embodiments of the present invention have derived relationships between the wavelength ratio width W of the mass addition film as well as the thickness ratio T_{R} and the magnitude of the ripple attributed to the transverse mode in the frequency characteristics regarding the acoustic wave device having the resonant frequency equal to or below about 1 GHz. Design parameters of the acoustic wave device concerning this derivation have been determined as follows:
Piezoelectric layer; material . . . LiTaO₃,
Metallic layers of IDT; layer structure . . . Ti layer/Al layer/Ti layer from piezoelectric layer side, thicknesses . . . t₁=about 30 nm/t₂=about 415 nm/t₃=about 4 nm from piezoelectric layer side,
Dielectric layer of IDT; material . . . SiO₂, thickness . . . t₅=about 30 nm,
Dielectric film; material . . . SiO₂, thickness . . . about 50 nm,
Wavelength λ . . . about 5.3 μm,
Duty ratio d . . . changed in increments of about 0.05 in a range from equal to or above about 0.4 to equal to or below about 0.8,
Al-equivalent normalized thickness T_{IDT} of electrode finger portion . . . about 3.77% or about 7.83%,
Material of mass addition film; Ta₂O₅,
Wavelength ratio width W of mass addition film; changed in increments of about 0.1 in a range from equal to or above about 0.8 to equal to or below about 2, and
Thickness ratio T_{R}; changed in increments of about 3% in a range from equal to or above about 10% to equal to or below about 40%.

The thickness ratio T_{R} was changed as described above by changing the thickness of the mass addition film depending on the Al-equivalent normalized thickness T_{IDT}. A return loss was measured every time the thickness ratio T_{R} and the wavelength ratio width W were changed, and the magnitude of the ripple attributed to the transverse mode was thus obtained.

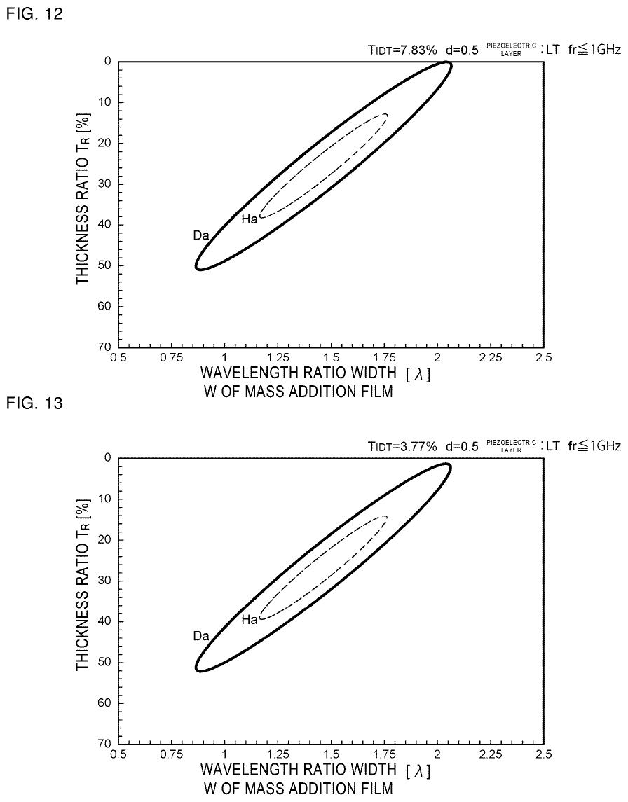

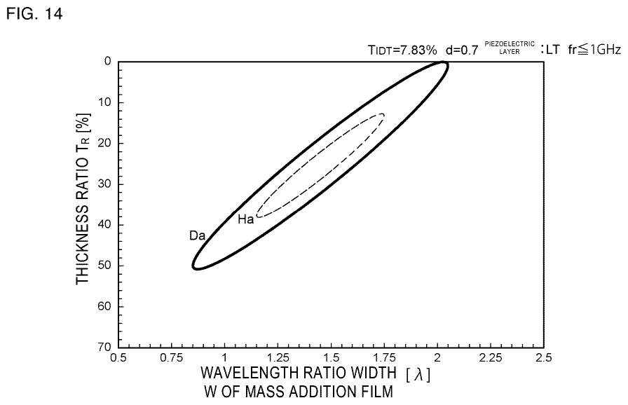

FIG. 12 is a diagram showing the relationship between the wavelength ratio width W of the mass addition film and the thickness ratio T_{R} that results in the magnitude of the ripple attributed to the transverse mode being equal to about 1 dB or about 0.3 dB in a case where the piezoelectric layer is made of lithium tantalate and the resonant frequency is equal to or below about 1 GHz and in a case where the Al-equivalent normalized thickness T_{IDT} of the electrode finger portion is equal to about 7.83% and the duty ratio d is equal to about 0.5. In FIG. 12, the value x on the xy plane corresponds to the value of the wavelength ratio width W and the value y thereon corresponds to the value of the thickness ratio T_{R}. In FIG. 12, lithium tantalate is denoted by LT and the resonant frequency is denoted by fr. The same applies to FIGS. 13 and 14 to be described later.

A solid ellipse Da expressed by the formula 3 and the formula 4 is plotted in FIG. 12. To be more precise, this ellipse Da is the ellipse with which the wavelength ratio width W of the mass addition film as the value x and the thickness ratio T_{R} as the value y are expressed by the afore-described formula 3 and formula 4 while setting the value t equal to or above about 0° and below about 360°. The ellipse Da substantially overlaps the values (x, y) that result in the magnitude of the ripple attributed to the transverse mode equal to about 1 dB in FIG. 12 within the range of the above-described design parameters. In FIG. 12, the values (x, y) that result in the magnitude of the above-described ripple equal to about 1 dB are plotted by the ellipse Da.

Accordingly, the transverse mode can more reliably be reduced or prevented since the wavelength ratio width W as the value x and the thickness ratio T_{R} as the value y have the values on the ellipse Da and within the range inside the ellipse Da. To be more precise, the magnitude of the ripple attributed to the transverse mode can more be reliably be reduced to equal to or below about 1 dB.

Nevertheless, the conditions to result in the magnitude of the ripple attributed to the transverse mode being equal to or below about 1 dB vary when the Al-equivalent normalized thickness T_{IDT} of the electrode finger portion and the duty ratio d are different. Given the circumstances, the Al-equivalent normalized thickness T_{IDT} of the electrode finger portion and the duty ratio d were changed, and the conditions to result in the magnitude of the ripple attributed to the transverse mode being equal to or below about 1 dB were desired regarding the respective cases. The ellipse Da expressed by the formula 3 and the formula 4 is the ellipse thus derived. As a consequence, the magnitude of the ripple attributed to the transverse mode can be set equal to or below about 1 dB in any case of the Al-equivalent normalized thickness T_{IDT} of the electrode finger portion and the duty ratio d as long as the wavelength ratio width W and the thickness ratio T_{R} have the values on the ellipse Da and within the range inside the ellipse Da. Examples of this feature will be shown in FIGS. 13 and 14.

FIG. 13 is a diagram showing a relationship between the wavelength ratio width W of the mass addition film and the thickness ratio T_{R} which results in the magnitude of the ripple attributed to the transverse mode being equal to about 1 dB or about 0.3 dB in the case where the piezoelectric layer is made of lithium tantalate with the resonant frequency being equal to or below about 1 GHz and in a case where the Al-equivalent normalized thickness T_{IDT} of the electrode finger portion is equal to about 3.77% and the duty ratio d is equal to about 0.5. FIG. 14 is a diagram showing a relationship between the wavelength ratio width W of the mass addition film and the thickness ratio T_{R} which results in the magnitude of the ripple attributed to the transverse mode being equal to about 1 dB or about 0.3 dB in the case where the piezoelectric layer is made of lithium tantalate with the resonant frequency being equal to or below about 1 GHz and in a case where the Al-equivalent normalized thickness T_{IDT} of the electrode finger portion is equal to about 7.83% and the duty ratio d is equal to about 0.7.

FIGS. 13 and 14 show results in the cases where the Al-equivalent normalized thickness T_{IDT} of the electrode finger portion or the duty ratio d is different from that in the case shown in FIG. 12. The ellipse Da expressed by the formula 3 and the formula 4 while setting the value t equal to or above about 0° and below about 360° is plotted in FIGS. 13 and 14 as well. The ellipse Da plotted in FIG. 13 substantially overlaps the values (x, y) that result in the magnitude of the ripple attributed to the transverse mode equal to about 1 dB in FIG. 13 within the range of the above-described design parameters. Similarly, the ellipse Da plotted in FIG. 14 substantially overlaps the values (x, y) that result in the magnitude of the ripple attributed to the transverse mode equal to about 1 dB in FIG. 14 within the range of the above-described design parameters. In FIGS. 13 and 14, the ellipse Da plots the values (x, y) that result in the magnitude of the above-described ripple equal to about 1 dB.

Accordingly, the transverse mode can be more reliably reduced or prevented in the cases shown in FIGS. 13 and 14 as well since the wavelength ratio width W of the mass addition film as the value x and the thickness ratio T_{R} as the value y have the values on the ellipse Da and within the range inside the ellipse Da. To be more precise, the magnitude of the ripple attributed to the transverse mode can more be reliably reduced to equal to or below about 1 dB. As described above, the transverse mode can be reduced or prevented in any case of the Al-equivalent normalized thickness T_{IDT} of the electrode finger portion and the duty ratio d.

A dashed ellipse Ha is plotted in FIG. 12. The ellipse Ha substantially overlaps the values (x, y) that result in the magnitude of the ripple attributed to the transverse mode equal to about 0.3 dB in FIG. 12 within the range of the above-described design parameters. In FIG. 12, the values (x, y) that result in the magnitude of the above-described ripple equal to about 0.3 dB are plotted by the ellipse Ha. Moreover, this ellipse Ha is the ellipse with which the wavelength ratio width W as the value x and the thickness ratio T_{R} as the value y are expressed by the following formula 3A and formula 4A while setting the value t equal to or above about 0° and below about 360°.

$$x = 0.08 \times cos t \times cos ( 1.3 ° ) - 12.8 \times sin t \times sin ( 1.3 ° ) + 2.22 - 2.54 \times d + 2.06 \times {d}^{2} \qquad Formula 3 A$$

$$y = 0.08 \times cos t \times sin ( 1.3 ° ) + 12.8 \times cos t \times sin ( 1.3 ° ) + 25.5 - 0.033 \times ( {T}_{IDT} - 7.83 ) \qquad Formula 4 A$$

The magnitude of the ripple attributed to the transverse mode can be more reliably reduced to equal to or below about 0.3 dB since the wavelength ratio width W as the value x and the thickness ratio T_{R} as the value y have the values on the ellipse Ha and within the range inside the ellipse Ha.

The ellipse Ha expressed by the formula 3A and the formula 4A while setting the value t equal to or above about 0° and below about 360° is also plotted in FIGS. 13 and 14. The ellipse Ha plotted in FIG. 13 substantially overlaps the values (x, y) that result in the magnitude of the ripple attributed to the transverse mode equal to about 0.3 dB in FIG. 13 within the range of the above-described design parameters. Similarly, the ellipse Ha plotted in FIG. 14 substantially overlaps the values (x, y) that result in the magnitude of the ripple attributed to the transverse mode equal to about 0.3 dB in FIG. 14 within the range of the above-described design parameters. In FIGS. 13 and 14, the ellipse Ha plots the values (x, y) that result in the magnitude of the above-described ripple equal to about 0.3 dB.

Accordingly, the transverse mode can be reduced or prevented more reliably and effectively in the cases shown in FIGS. 13 and 14 as well since the wavelength ratio width W of the mass addition film as the value x and the thickness ratio T_{R} as the value y have the values on the ellipse Ha and within the range inside the ellipse Ha. To be more precise, the magnitude of the ripple attributed to the transverse mode can be more reliably reduced to equal to or below about 0.3 dB. As described above, the transverse mode can be effectively reduced or prevented in any case of the Al-equivalent normalized thickness T_{IDT} of the electrode finger portion and the duty ratio d.

Here, the formula 3 and the formula 4 as well as the formula 3A and the formula 4A can be expressed by the following determinants.

$$Mathematical 1$$

$$( \begin{matrix}x \\ y\end{matrix} ) = ( \begin{matrix}cos θ & - sin θ \\ sin θ & cos θ\end{matrix} ) ( \begin{matrix}a cos t \\ b sin t\end{matrix} ) + ( \begin{matrix}{x}_{0} \\ {y}_{0}\end{matrix} )$$

$$Mathematical 2$$

$$( \begin{matrix}{x}_{0} \\ {y}_{0}\end{matrix} ) = ( \begin{matrix}2.22 - 2.54 \times d + 2.06 \times {d}^{2} \\ 25.5 - 0.033 \times ( {T}_{IDT} - 7.83 )\end{matrix} )$$

In the formula 3 and the formula 4, a=about 0.16, b=about 25.5, and θ=about 1.3 [° ] are used in the above-described determinant. In the formula 3A and the formula 4A, a=about 0.08, b=about 12.8, and θ=about 1.3 [° ] are used in the above-described determinant.

The acoustic wave device of the second example embodiment can suitably be used as an acoustic wave resonator in the low band filter device, for example. The acoustic wave device of the second example embodiment can more reliably reduce or prevent the transverse mode. Accordingly, the ripple in the frequency characteristics of the filter device can be more reliably reduced or prevented. Details of this feature will be described below.

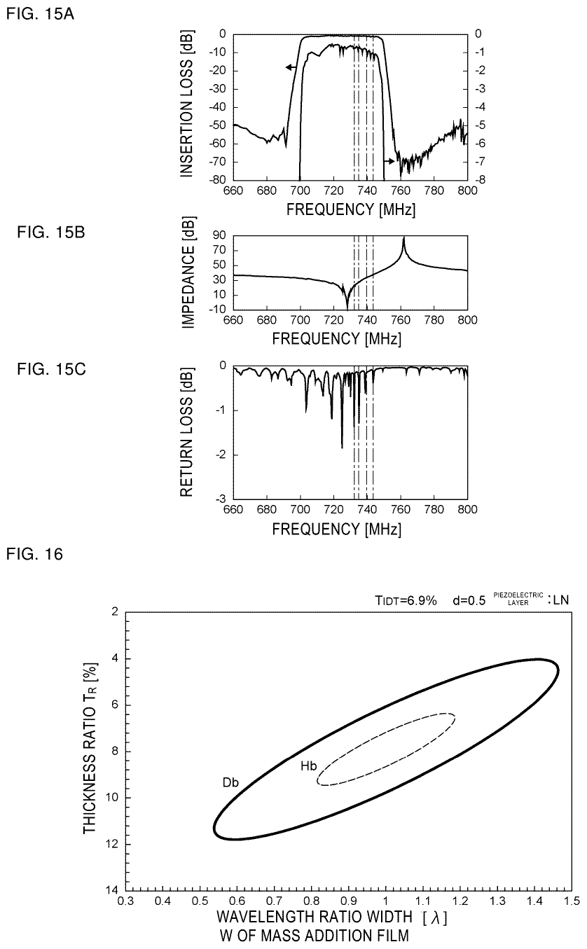

FIG. 15A is a diagram showing that ripples develop in attenuation frequency characteristics of the low band filter device. FIG. 15B is a diagram showing impedance frequency characteristics of the acoustic wave resonator used in the filter device that has the attenuation frequency characteristics according to FIG. 15A. FIG. 15C is a diagram showing a return loss of the acoustic wave resonator that has the impedance frequency characteristics according to FIG. 15B.

As shown in FIG. 15A, multiple ripples develop in the attenuation frequency characteristics of the filter device. Here, the multiple ripples develop in the pass band of the filter device. At the frequencies in which these ripples develop, the ripples also develop in the impedance frequency characteristics of the acoustic wave resonator as shown in FIG. 15B. Accordingly, unnecessary waves generated in the acoustic wave resonator used in the filter device cause the ripples to develop in the attenuation frequency characteristics of the filter device. Here, the multiple unnecessary waves that develop between a resonant frequency and an anti-resonant frequency and are plotted in FIG. 15B represent the transverse modes. When a ripple attributed to a transverse mode as a return loss of the acoustic wave resonator shown in FIG. 15C is larger, the ripple in the filter device shown in FIG. 15A tends to grow larger.

Relationships of the ripples in the frequency characteristics between the acoustic wave resonator and the filter device are the same or substantially the same as the relationships shown in FIGS. 10 and 11.

As described above, in the filter device, the magnitude of the ripple often needs to be, for example, equal to or below about 0.5 dB. According to the relationship shown with the dash-dotted straight line in FIG. 10, for example, the magnitude of the ripple in the attenuation frequency characteristics of the filter device can be set equal to or below about 0.5 dB by setting the magnitude of the ripple as the return loss in the acoustic wave resonator equal to or below about 1.8 dB. On the other hand, according to the relationship shown with the dash-dotted straight line in FIG. 11, for example, the magnitude of the ripple in the attenuation frequency characteristics of the filter device can be set equal to or below about 0.5 dB by setting the magnitude of the ripple as the return loss in the acoustic wave resonator equal to or below about 1 dB.

As described above, the magnitude of the ripple in the attenuation frequency characteristics of the filter device can be more reliably reduced to equal to or below about 0.5 dB by setting the magnitude of the ripple in the frequency characteristics of the acoustic wave device, which is used as the acoustic wave resonator in the filter device, equal to or below about 1 dB. As described above, in the second example embodiment, the magnitude of the ripple attributed to the transverse mode can more reliably be suppressed equal to or below 1 dB. Accordingly, in the case where the acoustic wave device of the second example embodiment is used in the filter device, the ripple in the attenuation frequency characteristics of the filter device can be more reliably reduced to equal to or below 0.5 dB as well. It is therefore possible to reduce or prevent deterioration of the filter characteristics of the filter device.

The third example embodiment is different from the first example embodiment in that the piezoelectric layer 6 shown by incorporating FIG. 2 is made of, for example, lithium niobate such as LiNbO₃. To be more precise, an acoustic wave device of the third example embodiment includes the piezoelectric substrate 2 and the IDT 27. Here, the piezoelectric substrate 2 only needs to include at least the high acoustic velocity material layer and the piezoelectric layer 6. As shown by incorporating FIG. 1, the mass addition films 9 are provided in the first edge region Ea and the second edge region Eb, respectively. Nonetheless, the mass addition film 9 only needs to be provided in at least one of the first edge region Ea and the second edge region Eb.

The third example embodiment includes the following features: 1) the piezoelectric layer 6 is made of lithium niobate; and 2) the wavelength ratio width W and the thickness ratio T_{R} have values within a range on an ellipse and inside of the ellipse expressed by the following formula 5 and formula 6 while setting the value t equal to or above 0° and below 360°. Here, the value t in the formula 5 and the formula 6 represents the angle and is different from the above-described thickness tₖ.

$$x = 0.22 \times cos t \times cos ( 6 ° ) - 3.9 \times sin t \times sin ( 6 ° ) + 1. + 0.4 \times ( d - 0.5 ) + 0.0022 \times ( {T}_{IDT} - 6.9 ) \qquad Formula 5$$

$$y = 0.22 \times cos t \times sin ( 6 ° ) + 3.9 \times cos t \times sin ( 6 ° ) + 7.9 - 0.033 \times ( {T}_{IDT} - 6.9 ) \qquad Formula 6$$

To be more precise, the inventors of example embodiments of the present invention have derived relationships between the wavelength ratio width W of the mass addition film as well as the thickness ratio T_{R} and the magnitude of the ripple attributed to the transverse mode in the frequency characteristics regarding the acoustic wave device in which the piezoelectric layer is made of lithium niobate. Design parameters of the acoustic wave device concerning this derivation have been determined as follows:
Piezoelectric layer; material . . . LiNbO₃,
Metallic layers of IDT; layer structure . . . Ti layer/Al layer/Ti layer from piezoelectric layer side, thicknesses . . . t₁=about 12 nm/t₂=about 100 nm/t₃=about 4 nm from piezoelectric layer side,
Dielectric layer of IDT; material . . . SiO₂, thickness . . . t₅=about 30 nm,
Dielectric film; material . . . SiO₂, thickness . . . about 30 nm,
Wavelength λ . . . about 1.3 μm, about 1.45 μm, or about 1.6 μm,
Duty ratio d . . . about 0.5 or about 0.7,
Al-equivalent normalized thickness T_{IDT} of electrode finger portion . . . about 7.24% or about 7.9%,
Material of mass addition film; Ta₂O₅,
Wavelength ratio width W of mass addition film; changed in increments of about 0.1 in a range from equal to or above about 0.6 to equal to or below about 1.3, and
Thickness ratio T_{R}; changed in increments of about 2% in a range from equal to or above about 4% to equal to or below about 10%.

The thickness ratio T_{R} was changed as described above by changing the thickness of the mass addition film depending on the Al-equivalent normalized thickness T_{IDT}. A return loss was measured every time the thickness ratio T_{R} and the wavelength ratio width W were changed, and the magnitude of the ripple attributed to the transverse mode was thus obtained.

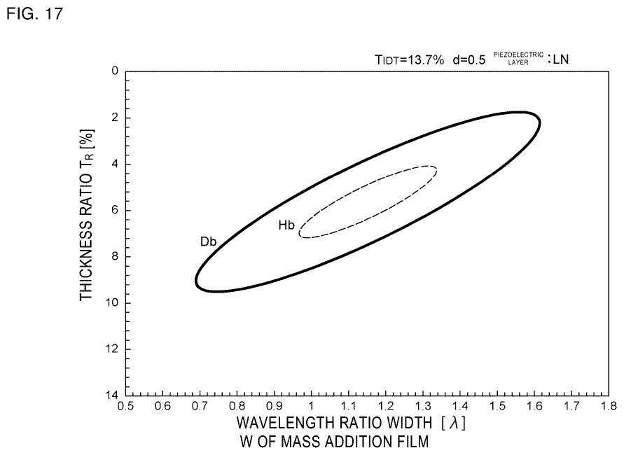

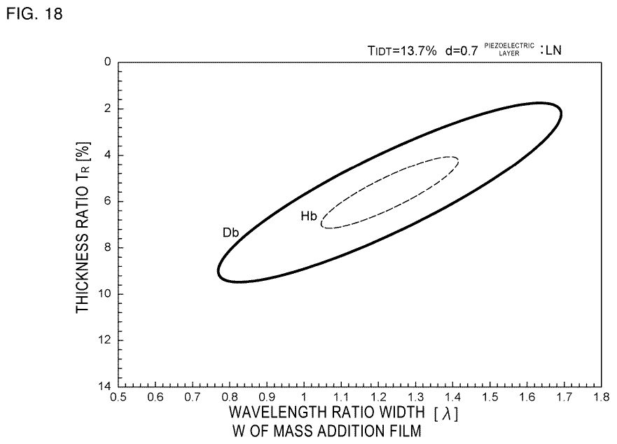

FIG. 16 is a diagram showing the relationship between the wavelength ratio width W of the mass addition film and the thickness ratio T_{R} that results in the magnitude of the ripple attributed to the transverse mode being equal to about 1 dB or about 0.2 dB in a case where the piezoelectric layer is made of lithium niobate and in a case where the Al-equivalent normalized thickness T_{IDT} of the electrode finger portion is equal to about 6.9% and the duty ratio d is equal to about 0.5. In FIG. 16, lithium niobate is denoted by LN. The same applies to FIGS. 17 and 18 to be described later.

A solid ellipse Db expressed by the formula 5 and the formula 6 is plotted in FIG. 16. To be more precise, this ellipse Db is the ellipse with which the wavelength ratio width W of the mass addition film as the value x and the thickness ratio T_{R} as the value y are expressed by the above-described formula 5 and formula 6 while setting the value t equal to or above about 0° and below about 360°. The ellipse Db substantially overlaps the values (x, y) that result in the magnitude of the ripple attributed to the transverse mode equal to about 1 dB in FIG. 16 within the range of the above-described design parameters.

Accordingly, the transverse mode can be more reliably reduced or prevented since the wavelength ratio width W as the value x and the thickness ratio T_{R} as the value y have the values on the ellipse Db and within the range inside the ellipse Db. To be more precise, the magnitude of the ripple attributed to the transverse mode can be more reliably reduced to equal to or below about 1 dB.

Nevertheless, the conditions to result in the magnitude of the ripple attributed to the transverse mode being equal to or below about 1 dB vary when the Al-equivalent normalized thickness T_{IDT} of the electrode finger portion and the duty ratio d are different. Given the circumstances, the Al-equivalent normalized thickness T_{IDT} of the electrode finger portion and the duty ratio d were changed, and the conditions to result in the magnitude of the ripple attributed to the transverse mode being equal to or below about 1 dB were desired regarding the respective cases. The ellipse Db expressed by the formula 5 and the formula 6 is the ellipse thus derived. As a consequence, the magnitude of the ripple attributed to the transverse mode can be set equal to or below about 1 dB in any case of the Al-equivalent normalized thickness T_{IDT} of the electrode finger portion and the duty ratio d as long as the wavelength ratio width W and the thickness ratio T_{R} have the values on the ellipse Db and within the range inside the ellipse Db. Examples of this feature will be shown in FIGS. 17 and 18.

FIG. 17 is a diagram showing a relationship between the wavelength ratio width W of the mass addition film and the thickness ratio T_{R} which results in the magnitude of the ripple attributed to the transverse mode being equal to about 1 dB or about 0.2 dB in the case where the piezoelectric layer is made of lithium niobate and in a case where the Al-equivalent normalized thickness T_{IDT} of the electrode finger portion is equal to about 13.7% and the duty ratio d is equal to about 0.5. FIG. 18 is a diagram showing a relationship between the wavelength ratio width W of the mass addition film and the thickness ratio T_{R} which results in the magnitude of the ripple attributed to the transverse mode being equal to about 1 dB or about 0.2 dB in the case where the piezoelectric layer is made of lithium niobate and in a case where the Al-equivalent normalized thickness T_{IDT} of the electrode finger portion is equal to about 13.7% and the duty ratio d is equal to about 0.7.

FIGS. 17 and 18 show results in the cases where the Al-equivalent normalized thickness T_{IDT} of the electrode finger portion or the duty ratio d is different from that in the case shown in FIG. 16. The ellipse Db expressed by the formula 5 and the formula 6 while setting the value t equal to or above about 0° and below about 360° is plotted in FIGS. 17 and 18 as well. The ellipse Db plotted in FIG. 17 substantially overlaps the values (x, y) that result in the magnitude of the ripple attributed to the transverse mode equal to about 1 dB in FIG. 17 within the range of the above-described design parameters. Similarly, the ellipse Db plotted in FIG. 18 substantially overlaps the values (x, y) that result in the magnitude of the ripple attributed to the transverse mode equal to about 1 dB in FIG. 18 within the range of the above-described design parameters. In FIGS. 17 and 18, the ellipse Db plots the values (x, y) that result in the magnitude of the above-described ripple equal to about 1 dB.

Accordingly, the transverse mode can be more reliably reduced or prevented in the cases shown in FIGS. 17 and 18 as well since the wavelength ratio width W of the mass addition film as the value x and the thickness ratio T_{R} as the value y have the values on the ellipse Db and within the range inside the ellipse Db. To be more precise, the magnitude of the ripple attributed to the transverse mode can be more reliably reduced to equal to or below about 1 dB. As described above, the transverse mode can be reduced or prevented in any case of the Al-equivalent normalized thickness T_{IDT} of the electrode finger portion and the duty ratio d.

A dashed ellipse Hb is plotted in FIG. 16. The ellipse Hb substantially overlaps the values (x, y) that result in the magnitude of the ripple attributed to the transverse mode equal to about 0.2 dB in FIG. 16 within the range of the above-described design parameters. In FIG. 16, the values (x, y) that result in the magnitude of the above-described ripple equal to about 0.2 dB are plotted by the ellipse Hb. Moreover, this ellipse Hb is the ellipse with which the wavelength ratio width W as the value x and the thickness ratio T_{R} as the value y are expressed by the following formula 5A and formula 6A while setting the value t equal to or above about 0° and below about 360°.

$$x = 0.088 \times cos t \times cos ( 6 ° ) - 1.56 \times sin t \times sin ( 6 ° ) + 1. + 0.4 \times ( d - 0.5 ) + 0.0022 \times ( {T}_{IDT} - 6.9 ) \qquad Formula 5 A$$

$$y = 0.088 \times cos t \times sin ( 6 ° ) + 1.56 \times cos t \times sin ( 6 ° ) + 7.9 - 0.033 \times ( {T}_{IDT} - 6.9 ) \qquad Formula 6 A$$

The magnitude of the ripple attributed to the transverse mode can be more reliably reduced to equal to or below about 0.2 dB since the wavelength ratio width W as the value x and the thickness ratio T_{R} as the value y have the values on the ellipse Hb and within the range inside the ellipse Hb.

The ellipse Hb expressed by the formula 5A and the formula 6A while setting the value t equal to or above about 0° and below about 360° is also plotted in FIGS. 17 and 18. The ellipse Hb plotted in FIG. 17 substantially overlaps the values (x, y) that result in the magnitude of the ripple attributed to the transverse mode equal to about 0.2 dB in FIG. 17 within the range of the above-described design parameters. Similarly, the ellipse Hb plotted in FIG. 18 substantially overlaps the values (x, y) that result in the magnitude of the ripple attributed to the transverse mode equal to about 0.2 dB in FIG. 18 within the range of the above-described design parameters. In FIGS. 17 and 18, the ellipse Hb plots the values (x, y) that result in the magnitude of the above-described ripple equal to about 0.2 dB.

Accordingly, the transverse mode can be reduced or prevented more reliably and effectively in the cases shown in FIGS. 17 and 18 as well since the wavelength ratio width W of the mass addition film of the mass addition film as the value x and the thickness ratio T_{R} as the value y have the values on the ellipse Hb and within the range inside the ellipse Hb. To be more precise, the magnitude of the ripple attributed to the transverse mode can be more reliably reduced to equal to or below about 0.2 dB. As described above, the transverse mode can be effectively reduced or prevented in any case of the Al-equivalent normalized thickness T_{IDT} of the electrode finger portion and the duty ratio d.

Here, the formula 5 and the formula 6 as well as the formula 5A and the formula 6A can be expressed by the following determinants.

$$Mathematical 3$$

$$( \begin{matrix}x \\ y\end{matrix} ) = ( \begin{matrix}cos θ & - sin θ \\ sin θ & cos θ\end{matrix} ) ( \begin{matrix}a cos t \\ b sin t\end{matrix} ) + ( \begin{matrix}{x}_{0} \\ {y}_{0}\end{matrix} )$$

$$Mathematical 4$$

$$( \begin{matrix}{x}_{0} \\ {y}_{0}\end{matrix} ) = ( \begin{matrix}1. + 0.4 \times ( d - 0.5 ) + 0.0022 \times ( {T}_{IDT} - 6.9 ) \\ 7.9 - 0.033 \times ( {T}_{IDT} - 6.9 )\end{matrix} )$$

In the formula 5 and the formula 6, a=about 0.22, b=about 3.9, and about θ=6 [° ] are used in the above-described determinant. In the formula 5A and the formula 6A, a=about 0.088, b=about 1.56, and θ=about 6 [° ] are used in the above-described determinant.

The acoustic wave device of the third example embodiment can suitably be used as an acoustic wave resonator in a filter device, for example. The acoustic wave device of the third example embodiment can more reliably reduce or prevent the transverse mode. Moreover, as shown in FIG. 10, for example, the magnitude of the ripple in the attenuation frequency characteristics of the filter device can be set equal to or below about 0.5 dB by setting the magnitude of the ripple as the return loss in the acoustic wave resonator equal to or below about 1.8 dB. Alternatively, as shown in FIG. 11, for example, the magnitude of the ripple in the attenuation frequency characteristics of the filter device can be set equal to or below about 0.5 dB by setting the magnitude of the ripple as the return loss in the acoustic wave resonator equal to or below about 1 dB.

In the third example embodiment, the magnitude of the ripple attributed to the transverse mode can be more reliably reduced to equal to or below about 1 dB. Accordingly, in the case where the acoustic wave device of the third example embodiment is used in the filter device, the ripple in the attenuation frequency characteristics of the filter device can be more reliably reduced to equal to or below about 0.5 dB as well. It is therefore possible to reduce or prevent deterioration of the filter characteristics of the filter device.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a high acoustic velocity material layer;
a piezoelectric layer on the high acoustic velocity material layer and including lithium tantalate; and
an interdigital transducer (IDT) on the piezoelectric layer and including a plurality of electrode finger portions each including at least one electrode finger portion layer; wherein
an acoustic velocity of a bulk wave that propagates in the high acoustic velocity material layer is higher than an acoustic velocity of an acoustic wave that propagates in the piezoelectric layer;
when a direction of extension of the plurality of electrode finger portions is defined as an electrode finger portion extending direction and the IDT is viewed in a direction orthogonal or substantially orthogonal to the electrode finger portion extending direction, a region where adjacent electrode finger portions of the plurality of electrode finger portions overlap each other is an intersection region, and the intersection region includes a central region and a pair of edge regions sandwiching the central region in the electrode finger portion extending direction;
the acoustic wave device further includes a mass addition film at at least one of the edge regions and continuously provided so as to overlap the plurality of electrode finger portions and regions between the plurality of electrode finger portions in plan view;
a resonant frequency is higher than about 1 GHz;
when a wavelength defined by an electrode finger portion pitch of the IDT is denoted by λ, a value obtained by dividing a product of a density and a thickness of an arbitrary layer by a density of Al and the wavelength λ and expressed in percentage is defined as an Al-equivalent normalized thickness of the arbitrary layer, a sum of the Al-equivalent normalized thicknesses of the electrode finger portion layers is defined as T_{IDT} [%] representing the Al-equivalent normalized thickness of the plurality of electrode finger portions, the Al-equivalent normalized thickness of the mass addition film is defined as Tₘ[%], and a value obtained by dividing a thickness ratio of the Al-equivalent normalized thickness Tₘ of the mass addition film relative to the Al-equivalent normalized thickness T_{IDT} of the plurality of electrode finger portions by about 3.15 is defined as T_{R} [%], T_{R}=(1/3.15)× (Tₘ/T_{IDT})×100 [%] is satisfied; and
when a duty ratio of the IDT is denoted by d, a value obtained by dividing a dimension in the electrode finger portion extending direction of the mass addition film by the wavelength λ is defined as a wavelength ratio width W, a value x corresponds to a value of the wavelength ratio width W, and a value y corresponds to a value of the thickness ratio T_{R}, the wavelength ratio width W and the thickness ratio T_{R} have values within a range on an ellipse and inside of the ellipse on xy plane expressed by a formula 1 and a formula 2 defined below while setting a value t equal to or above about 0° and below about 360°:
$$x = 0.19 \times cos ( - 5.5 ° ) \times cos θ - 0.021 \times sin ( - 5.5 ° ) \times sin θ + 0.0146 \times {T}_{IDT}^{2} - 0.229 \times {T}_{IDT} + 1.5611 + 0.4 \times ( d - 0.55 ) ; and \qquad Formula 1$$
$$y = 0.19 \times sin ( - 5.5 ° ) \times cos θ + 0.021 \times cos ( - 5.5 ° ) \times sin θ + 10.15 . \qquad Formula 2$$

2. The acoustic wave device according to claim 1, further comprising:
a plurality of the mass addition films; wherein
the plurality of mass addition films are provided at both of the edge regions, respectively.

3. The acoustic wave device according to claim 1, wherein
the IDT includes an IDT electrode;
the acoustic wave device further includes a dielectric film on the piezoelectric layer and covering the IDT electrode; and
the at least one electrode finger portion layer includes a metallic layer included in the IDT electrode, and a dielectric layer included in the dielectric film.

4. The acoustic wave device according to claim 3, wherein the mass addition film is provided between the metallic layer and the dielectric layer in the edge region.

5. The acoustic wave device according to claim 4, wherein a density of the mass addition film is higher than a density of the dielectric layer.

6. The acoustic wave device according to claim 1, wherein the mass addition film includes tantalum oxide.

7. The acoustic wave device according to claim 1, wherein the high acoustic velocity material layer is a high acoustic velocity support substrate.

8. The acoustic wave device according to claim 1, further comprising:
a support substrate; wherein
the high acoustic velocity material layer is a high acoustic velocity film provided between the support substrate and the piezoelectric layer.

9. The acoustic wave device according to claim 1, further comprising:
a low acoustic velocity film between the high acoustic velocity material layer and the piezoelectric layer; wherein
an acoustic velocity of a bulk wave that propagates in the low acoustic velocity film is lower than an acoustic velocity of a bulk wave that propagates in the piezoelectric layer.

10. An acoustic wave device comprising:
a high acoustic velocity material layer;
a piezoelectric layer on the high acoustic velocity material layer and including lithium tantalate; and
an interdigital transducer (IDT) on the piezoelectric layer and including a plurality of electrode finger portions each including at least one electrode finger portion layer; wherein
an acoustic velocity of a bulk wave that propagates in the high acoustic velocity material layer is higher than an acoustic velocity of an acoustic wave that propagates in the piezoelectric layer;
when a direction of extension of the plurality of electrode finger portions is defined as an electrode finger portion extending direction and the IDT is viewed in a direction orthogonal or substantially orthogonal to the electrode finger portion extending direction, a region where adjacent electrode finger portions of the plurality of electrode finger portions overlap each other is an intersection region, and the intersection region includes a central region and a pair of edge regions sandwiching the central region in the electrode finger portion extending direction;
the acoustic wave device further includes a mass addition film at at least one of the edge regions and continuously provided so as to overlap the plurality of electrode finger portions and regions between the plurality of electrode finger portions in plan view;
a resonant frequency is higher than about 1 GHz;
when a wavelength defined by an electrode finger portion pitch of the IDT is denoted by λ, a value obtained by dividing a product of a density and a thickness of an arbitrary layer by a density of Al and the wavelength λ and expressed in percentage is defined as an Al-equivalent normalized thickness of the layer, a sum of the Al-equivalent normalized thicknesses of the electrode finger portion layers is defined as T_{IDT} [%] representing the Al-equivalent normalized thickness of the plurality of electrode finger portions, the Al-equivalent normalized thickness of the mass addition film is defined as Tₘ [%], and a value obtained by dividing a thickness ratio of the Al-equivalent normalized thickness Tₘ of the mass addition film relative to the Al-equivalent normalized thickness T_{IDT} of the plurality of electrode finger portions by about 3.15 is defined as T_{R} [%], T_{R}=(1/3.15)× (Tₘ/T_{IDT})×100 [%] is satisfied; and
when a duty ratio of the IDT is denoted by d and a value obtained by dividing a dimension in the electrode finger portion extending direction of the mass addition film by the wavelength λ is defined as a wavelength ratio width W, the wavelength ratio width W of the mass addition film satisfies 0.88×{0.0101×T_{IDT}²−0.1677×T_{IDT}+1.3201+0.4×(d−0.55)}≤W≤1.12×{0.0101×T_{IDT}²−0.1677×T_{IDT}+1.3201+0.4×(d−0.55)}; and
the thickness ratio T_{R} satisfies 0.88×10.7≤T_{R}≤1.12×10.7.

11. The acoustic wave device according to claim 10, further comprising:
a plurality of the mass addition films; wherein
the plurality of mass addition films are provided at both of the edge regions, respectively.

12. The acoustic wave device according to claim 10, wherein
the IDT includes an IDT electrode;
the acoustic wave device further includes a dielectric film on the piezoelectric layer and covering the IDT electrode; and
the at least one electrode finger portion layer includes a metallic layer included in the IDT electrode, and a dielectric layer included in the dielectric film.

13. The acoustic wave device according to claim 12, wherein the mass addition film is provided between the metallic layer and the dielectric layer in the edge region.

14. The acoustic wave device according to claim 13, wherein a density of the mass addition film is higher than a density of the dielectric layer.

15. An acoustic wave device comprising:
a high acoustic velocity material layer;
a piezoelectric layer on the high acoustic velocity material layer and including lithium tantalate; and
an interdigital transducer (IDT) on the piezoelectric layer and including a plurality of electrode finger portions each including at least one electrode finger portion layer; wherein
an acoustic velocity of a bulk wave that propagates in the high acoustic velocity material layer is higher than an acoustic velocity of an acoustic wave that propagates in the piezoelectric layer;
when a direction of extension of the plurality of electrode finger portions is defined as an electrode finger portion extending direction and the IDT is viewed in a direction orthogonal or substantially orthogonal to the electrode finger portion extending direction, a region where adjacent electrode finger portions of the plurality of electrode finger portions overlap each other is an intersection region, and the intersection region includes a central region and a pair of edge regions sandwiching the central region in the electrode finger portion extending direction;
the acoustic wave device further includes a mass addition film at at least one of the edge regions and continuously provided so as to overlap the plurality of electrode finger portions and regions between the plurality of electrode finger portions in plan view;
a resonant frequency is equal to or below about 1 GHz;
when a wavelength defined by an electrode finger portion pitch of the IDT is denoted by λ, a value obtained by dividing a product of a density and a thickness of an arbitrary layer by a density of Al and the wavelength λ and expressed in percentage is defined as an Al-equivalent normalized thickness of the layer, a sum of the Al-equivalent normalized thicknesses of the electrode finger portion layers is defined as T_{IDT} [%] representing the Al-equivalent normalized thickness of the plurality of electrode finger portions, the Al-equivalent normalized thickness of the mass addition film is defined as Tₘ[%], and a value obtained by dividing a thickness ratio of the Al-equivalent normalized thickness Tₘ of the mass addition film relative to the Al-equivalent normalized thickness T_{IDT} of the plurality of electrode finger portion by about 3.15 is defined as T_{R} [%], T_{R}=(1/3.15)× (Tₘ/T_{IDT})×100 [%] is satisfied; and
when a duty ratio of the IDT is denoted by d, a value obtained by dividing a dimension in the electrode finger portion extending direction of the mass addition film by the wavelength λ is defined as a wavelength ratio width W, a value x corresponds to a value of the wavelength ratio width W, and a value y corresponds to a value of the thickness ratio T_{R}, the wavelength ratio width W and the thickness ratio T_{R} have values within a range on an ellipse and inside of the ellipse on xy plane expressed by a formula 3 and a formula 4 while setting a value t equal to or above about 0° and below about 360°:
$$x = 0.16 \times cos t \times cos ( 1.3 ° ) - 25.5 \times sin t \times sin ( 1.3 ° ) + 2.22 - 2.54 \times d + 2.06 \times {d}^{2} ; and \qquad Formula 3$$
$$y = 0.16 \times cos t \times sin ( 1.3 ° ) + 25.5 \times cos t \times sin ( 1.3 ° ) + 25.5 - 0.033 \times ( {T}_{IDT} - 7.83 ) . \qquad Formula 4$$

16. The acoustic wave device according to claim 15, further comprising:
a plurality of the mass addition films; wherein
the plurality of mass addition films are provided at both of the edge regions, respectively.

17. The acoustic wave device according to claim 15, wherein
the IDT includes an IDT electrode;
the acoustic wave device further includes a dielectric film on the piezoelectric layer and covering the IDT electrode; and
the at least one electrode finger portion layer includes a metallic layer included in the IDT electrode, and a dielectric layer included in the dielectric film.

18. An acoustic wave device comprising:
a high acoustic velocity material layer;
a piezoelectric layer on the high acoustic velocity material layer and including lithium niobate; and
an interdigital transducer (IDT) provided on the piezoelectric layer and including a plurality of electrode finger portions each including at least one electrode finger portion layer; wherein
an acoustic velocity of a bulk wave that propagates in the high acoustic velocity material layer is higher than an acoustic velocity of an acoustic wave that propagates in the piezoelectric layer;
when a direction of extension of the plurality of electrode finger portions is defined as an electrode finger portion extending direction and the IDT is viewed in a direction orthogonal or substantially orthogonal to the electrode finger portion extending direction, a region where adjacent electrode finger portions of the plurality of electrode finger portions overlap each other is an intersection region, and the intersection region includes a central region and a pair of edge regions sandwiching the central region in the electrode finger portion extending direction;
the acoustic wave device further includes a mass addition film at at least one of the edge regions and continuously provided so as to overlap the plurality of electrode finger portions and regions between the plurality of electrode finger portions in plan view;
when a wavelength defined by an electrode finger portion pitch of the IDT is denoted by λ, a value obtained by dividing a product of a density and a thickness of an arbitrary layer by a density of Al and the wavelength λ and expressed in percentage is defined as an Al-equivalent normalized thickness of the layer, a sum of the Al-equivalent normalized thicknesses of the electrode finger portion layers is defined as T_{IDT} [%] representing the Al-equivalent normalized thickness of the plurality of electrode finger portions, the Al-equivalent normalized thickness of the mass addition film is defined as Tₘ [%], and a value obtained by dividing a thickness ratio of the Al-equivalent normalized thickness Tₘ of the mass addition film relative to the Al-equivalent normalized thickness T_{IDT} of the plurality of electrode finger portions by about 3.15 is defined as T_{R} [%], T_{R}=(1/3.15)×(Tₘ/T_{IT})×100 [%] is satisfied; and
when a duty ratio of the IDT is denoted by d, a value obtained by dividing a dimension in the electrode finger portion extending direction of the mass addition film by the wavelength λ is defined as a wavelength ratio width W, a value x corresponds to a value of the wavelength ratio width W, and a value y corresponds to a value of the thickness ratio T_{R}, the wavelength ratio width W and the thickness ratio T_{R} have values within a range on an ellipse and inside of the ellipse on xy plane expressed by a formula 5 and a formula 6 while setting a value t equal to or above about 0° and below about 360°:
$$x = 0.22 \times cos t \times cos ( 6 ° ) - 3.9 \times sin t \times sin ( 6 ° ) + 1. + 0.4 \times ( d - 0.5 ) + 0.0022 \times ( {T}_{IDT} - 6.9 ) ; and \qquad Formula 5$$
$$y = 0.22 \times cos t \times sin ( 6 ° ) + 3.9 \times cos t \times sin ( 6 ° ) + 7.9 - 0.033 \times ( {T}_{IDT} - 6.9 ) . \qquad Formula 6$$

19. The acoustic wave device according to claim 18, further comprising:
a plurality of the mass addition films; wherein
the plurality of mass addition films are provided at both of the edge regions, respectively.

20. The acoustic wave device according to claim 18, wherein
the IDT includes an IDT electrode;
the acoustic wave device further includes a dielectric film on the piezoelectric layer and covering the IDT electrode; and
the at least one electrode finger portion layer includes a metallic layer included in the IDT electrode, and a dielectric layer included in the dielectric film.
